(19) United States
(12) Patent Application Publication
(10) Pub. No.: US 2025/0369099 A1
(43) Pub. Date: Dec. 4, 2025

(54) DEPOSITION MASK

(71) Applicant: Samsung Display Co., LTD., Yongin-si (KR)

(72) Inventors: Sung Woon KIM, Yongin-si (KR); Jeong Kuk KIM, Yongin-si (KR); Ji Hyun JUNG, Yongin-si (KR)

(21) Appl. No.: 19/030,920

(22) Filed: Jan. 17, 2025

(30) Foreign Application Priority Data
May 31, 2024 (KR) 10-2024-0071436

(51) Int. Cl. C23C 16/04

(52) U.S. Cl. CPC C23C 16/042

(57) ABSTRACT

A deposition mask is provided. The deposition mask includes a substrate including a plurality of cell regions, a mask lip region partitioning the plurality of cell regions, and an outer frame region outside the plurality of cell regions, a mask membrane including a first inorganic film on the substrate corresponding to the plurality of cell regions, and a warpage compensation pattern including a second inorganic film on the substrate corresponding to the outer frame region. A material of the first inorganic film is a material that exerts stress on the substrate in a first reference direction. A material of the second inorganic film is a material that exerts stress on the substrate in the first reference direction.

### CROSS-REFERENCE TO RELATED APPLICATION

The present application claims priority to and the benefit of Korean Patent Application No. 10-2024-0071436, filed on May 31, 2024, in the Korean Intellectual Property Office, the entire disclosure of which is incorporated by reference herein.

### BACKGROUND

### 1. Field

One or more embodiments of the present disclosure relate to a deposition mask.

### 2. Description of the Related Art

Wearable devices that form a focus at a distance close to user's eyes have been developed in the form of glasses or helmets. For example, the wearable device may be a head mounted display (HMD) device, augmented reality (AR) glasses, and/or the like. These wearable devices provide an AR screen and/or a virtual reality (VR) screen to the user.

Generally, wearable devices such as the HMD device or the AR glasses require a display specification of at least 2000 PPI (pixels per inch) to ensure prolonged use without causing dizziness. To achieve this, organic light-emitting diode on silicon (OLEDoS) technology, which is a high-resolution small organic light-emitting display device, is emerging. The organic light-emitting diode on silicon (OLEDoS) involves placing an organic light-emitting diode (OLED) on a semiconductor wafer substrate that has a complementary metal oxide semiconductor (CMOS) arranged on it.

### SUMMARY

Aspects of embodiments of the present disclosure are directed towards a deposition mask capable of reducing stress caused by the difference in physical properties between a substrate of the mask and a thin film stacked on the substrate, and capable of reducing warpage, which is the bending characteristic of the mask.

However, aspects of the present disclosure are not restricted to those set forth herein. The above and other aspects of the present disclosure will become more apparent to one of ordinary skill in the art to which the present disclosure pertains by referencing the detailed description of the present disclosure.

According to one or more embodiments of the present disclosure, a deposition mask may include a substrate including a plurality of cell regions, a mask lip region partitioning the plurality of cell regions, and an outer frame region outside the plurality of cell regions, a mask membrane including a first inorganic film arranged on (e.g., disposed on) the substrate corresponding to the plurality of cell regions, and a warpage compensation pattern including a second inorganic film arranged (e.g., disposed on) on the substrate corresponding to the outer frame region. A material of the first inorganic film is a material that exerts stress on the substrate in a first reference direction. A material of the second inorganic film is a material that exerts stress on the substrate in the first reference direction.

In some embodiments, the material of the first inorganic film and the material of the second inorganic film may be the same.

In some embodiments, the warpage compensation pattern may be arranged in (e.g., disposed in) a ring shape around (e.g., surrounding) a periphery of the plurality of cell regions.

In some embodiments, the warpage compensation pattern may include at least one slit exposing a surface of the substrate.

In some embodiments, a first exposed region of the substrate may be arranged between the warpage compensation pattern and the plurality of cell regions, where the first inorganic film and the second inorganic film are removed to expose the surface of the substrate.

In some embodiments, a second exposed region of the substrate is arranged outside the warpage compensation pattern, where the first inorganic film and the second inorganic film are removed to expose the surface of the substrate.

In some embodiments, the stress in the first reference direction may be compressive stress.

In some embodiments, the deposition mask may further include an alignment key including a first metal arranged in a portion of the outer frame region. The first metal may be a material that exerts tensile stress on the substrate. The first metal may not be arranged in a remaining portion of the outer frame region except for the portion of the outer frame region where the alignment key is arranged.

In some embodiments, materials of the first inorganic film and the second inorganic film include silicon nitride (SiNₓ). A material of the first metal includes tungsten (W).

In some embodiments, the stress in the first reference direction may be tensile stress.

In some embodiments, the deposition mask may further include an alignment key including a second metal arranged in a portion of the outer frame region. The second metal may be a material that exerts compressive stress on the substrate. The second metal may not be arranged in a remaining portion of the outer frame region except for the portion of the outer frame region where the alignment key is arranged.

According to one or more embodiments of the present disclosure, a deposition mask including a substrate including a plurality of cell regions, a mask lip region partitioning the plurality of cell regions, and an outer frame region outside the plurality of cell regions, a mask membrane including a plating film arranged on (e.g., disposed on) the substrate corresponding to the plurality of cell regions, and a warpage compensation pattern including an inorganic film arranged on (e.g., disposed on) the substrate corresponding to the outer frame region. A material of the plating film is a material that exerts stress on the substrate in a first reference direction. A material of the inorganic film is a material that exerts stress on the substrate in the first reference direction.

In some embodiments, the warpage compensation pattern may be arranged in (e.g., disposed in) a ring shape around (e.g., surrounding) a periphery of the plurality of cell regions.

In some embodiments, the warpage compensation pattern may include at least one slit exposing a surface of the substrate.

In some embodiments, a first exposed region of the substrate may be arranged between the warpage compensation pattern and the plurality of cell regions, where the inorganic film is removed to expose the surface of the substrate.

In some embodiments, a second exposed region of the substrate may be arranged outside the warpage compensation pattern, where the inorganic film is removed to expose the surface of the substrate.

In some embodiments, the stress in the first reference direction may be compressive stress.

In some embodiments, the deposition mask may further include an alignment key including a first metal arranged in a portion of the outer frame region. The first metal may be a material that exerts tensile stress on the substrate. The first metal may not be arranged in a remaining portion of the outer frame region except for the portion of the outer frame region where the alignment key is arranged.

In some embodiments, the stress in the first reference direction may be tensile stress.

In some embodiments, the deposition mask may further include an alignment key including a second metal arranged in a portion of the outer frame region. The second metal may be a material that exerts compressive stress on the substrate. The second metal may not be arranged in a remaining portion of the outer frame region except for the portion of the outer frame region where the alignment key is arranged.

According to the aforementioned and one or more embodiments of the present disclosure, stress caused by the difference in physical properties between the substrate of the mask and the thin film stacked on the substrate may be reduced, and warpage, which is the bending characteristic of the mask, may be reduced.

According to the aforementioned and one or more embodiments of the present disclosure, by reducing the warpage, which is the bending characteristic of the mask, it is possible to reduce issues of mask damage during a deposition process utilizing the mask and during a mask cleaning process.

### BRIEF DESCRIPTION OF THE DRAWINGS

The above and one or more embodiments of the present disclosure will become more apparent by describing embodiments thereof with reference to the attached drawings, in which:

FIG. 1 is an exploded perspective view showing a display device according to one or more embodiments;

FIG. 2 is a block diagram illustrating a display device according to one or more embodiments;

FIG. 3 is an equivalent circuit diagram of a first sub-pixel according to one or more embodiments;

FIG. 4 is a layout diagram illustrating an example of a display panel according to one or more embodiments;

FIGS. 5 and 6 are each a layout diagram illustrating an embodiment of the display area of FIG. 4;

FIG. 7 is a cross-sectional view illustrating an example of a display panel taken along the line I1-I1′ of FIG. 5;

FIG. 8 is a perspective view illustrating a head mounted display according to one or more embodiments;

FIG. 9 is an exploded perspective view illustrating an example of the head mounted display of FIG. 8;

FIG. 10 is a perspective view illustrating a head mounted display according to one or more embodiments;

FIG. 11 is a perspective view of a mask according to one or more embodiments;

FIG. 12 is a schematic plan view of a mask according to one or more embodiments;

FIG. 13 is a schematic plan view of a mask according to a comparative example;

FIG. 14 is a cross-sectional view of the mask shown in FIG. 13;

FIGS. 15 and 16 are each a conceptual diagram illustrating stress exerted on a substrate by a thin film deposited on the substrate;

FIG. 17 is a conceptual diagram illustrating a warpage of the mask shown in FIG. 13;

FIG. 18 is a schematic plan view of a mask according to one or more embodiments;

FIG. 19 is a cross-sectional view of the mask shown in FIG. 18;

FIG. 20 is a conceptual diagram illustrating the warpage of the mask shown in FIG. 18;

FIG. 21 is a schematic plan view of a mask according to one or more embodiments;

FIG. 22 is a cross-sectional view of the mask shown in FIG. 21;

FIG. 23 is a plan view of a mask according to one or more embodiments in which the area of a warpage compensation pattern is enlarged;

FIG. 24 is a plan view of a mask according to one or more embodiments in which a warpage compensation pattern includes a slit;

FIG. 25 is a plan view of a mask according to one or more embodiments in which a mask membrane include a plating film; and

FIG. 26 is a cross-sectional view of the mask shown in FIG. 25.

### DETAILED DESCRIPTION

Aspects and features of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in one or more suitable different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, and/or one or more (e.g., any suitable) combinations thereof denote like elements throughout the attached drawings and the written description, and thus, descriptions thereof will not be repeated, and duplicative descriptions thereof may not be provided. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, and/or the like., of the elements, unless specified.

One or more suitable embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in one or more suitable different ways, all without departing from the spirit or scope of the present disclosure and equivalents thereof.

In the detailed description, for the purposes of explanation, numerous specific details are set forth to provide a thorough understanding of one or more suitable embodiments. It is apparent, however, that one or more suitable embodiments may be practiced without these specific details or with one or more equivalent arrangements. In other instances, well-known structures and devices are shown in block diagram form to avoid unnecessarily obscuring one or more suitable embodiments.

Spatially relative terms, such as “beneath,” “below,” “lower,” “under,” “above,” “upper,” and/or the like, may be used herein for ease of explanation to describe one element or feature's relationship to another element(s) or feature(s) as illustrated in the drawings. It will be understood that the spatially relative terms are intended to encompass different orientations of the device in use or in operation, in addition to the orientation depicted in the drawings. For example, if (e.g., when) the device in the drawings is turned over, elements described as “below” or “beneath” or “under” other elements or features would then be oriented “above” the other elements or features. Thus, the example terms “below” and “under” can encompass both (e.g., simultaneously) an orientation of above and below. The device may be otherwise oriented (e.g., rotated 90 degrees or at other orientations) and the spatially relative descriptors used herein should be interpreted accordingly. Similarly, if (e.g., when) a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” refers to viewing a target portion from the top, and the phrase “on a cross-section” refers to viewing a cross-section formed by vertically cutting a target portion from the side.

It will be understood that if (e.g., when) an element, layer, region, or component is referred to as being “formed on,” “on,” “connected to,” or “coupled to” another element, layer, region, or component, it can be directly formed on, on, connected to, and/or coupled to the other element, layer, region, and/or component, or indirectly formed on, on, connected to, and/or coupled to the other element, layer, region, and/or component, such that one or more intervening elements, layers, regions, and/or components may be present. For example, if (e.g., when) a layer, region, and/or component is referred to as being “electrically connected” or “electrically coupled” to another layer, region, and/or component, it can be directly electrically connected or coupled to the other layer, region, and/or component or intervening layers, regions, and/or components may be present. However, “directly connected/directly coupled” refers to one component directly connecting or coupling another component without an intermediate component. In some embodiments, other expressions describing relationships between components, such as “between,” “immediately between” and/or “adjacent to” and “directly adjacent to” may be construed similarly. In addition, it will also be understood that if (e.g., when) an element or layer is referred to as being “between” two elements or layers, it can be the only element or layer between the two elements or layers, or one or more intervening elements or layers may also be present.

For the purposes of the present disclosure, expressions, such as “at least one of,” “one of,” and “selected from among,” if (e.g., when) preceding a list of elements, modify the entire list of elements and do not modify the individual elements of the list. For example, “at least one of X, Y, and Z,” “at least one of X, Y, or Z,” and “at least one selected from among the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression, such as “at least one of A and/or B” may include A, B, or A and B. As used herein, the term “and/or” includes any and all combinations of one or more of the associated listed items. For example, the expression, such as “A and/or B” may include A, B, or A and B. Further, the use of “may” if (e.g., when) describing embodiments of the present disclosure refers to “one or more embodiments of the present disclosure”.

It will be understood that, although the terms “first,” “second,” “third,” and/or the like, may be used herein to describe one or more suitable elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer, and/or section described could be termed a second element, component, region, layer, and/or section, without departing from the spirit and scope of the present disclosure and equivalents thereof.

In one or more embodiments, the x-axis, the y-axis, and/or the z-axis are not limited to three axes of a rectangular coordinate system, and may be interpreted in a broader sense. For example, the x-axis, the y-axis, and the z-axis may be normal (e.g., perpendicular) to one another, or may represent different directions that are not normal (e.g., perpendicular) to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprise,” “comprises,” “comprising,” “have,” “has,” “having,” “include,” “includes,” and “including,” if (e.g., when) used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and/or similar terms are used as terms of approximation and not as terms of degree, and are intended to account for the inherent deviations in measured or calculated values that would be recognized by those of ordinary skill in the art. “About” or “approximately,” as used herein, is inclusive of the stated value and refers to within an acceptable range of deviation for the particular value as determined by one of ordinary skill in the art, considering the measurement in question and the error associated with measurement of the particular quantity (e.g., the limitations of the measurement system). For example, “about” may refer to within one or more standard deviations, or within ±30%, 20%, 10%, 5% of the stated value. Further, the use of “may” if (e.g., when) describing embodiments of the present disclosure refers to “one or more embodiments of the present disclosure.”

If (e.g., when) one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, and/or a (e.g., any suitable) combination of software, firmware, and hardware. For example, one or more suitable components of these devices may be formed on one integrated circuit (IC) chip or on separate IC chips. Further, the one or more suitable components of these devices may be implemented on a flexible printed circuit film, a tape carrier package (TCP), a printed circuit board (PCB), or formed on one substrate.

Further, the one or more suitable components of these devices may be a process or thread, running on one or more processors, in one or more computing devices, executing computer program instructions and interacting with other system components for performing the one or more suitable functionalities described herein. The computer program instructions are stored in a memory which may be implemented in a computing device utilizing a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

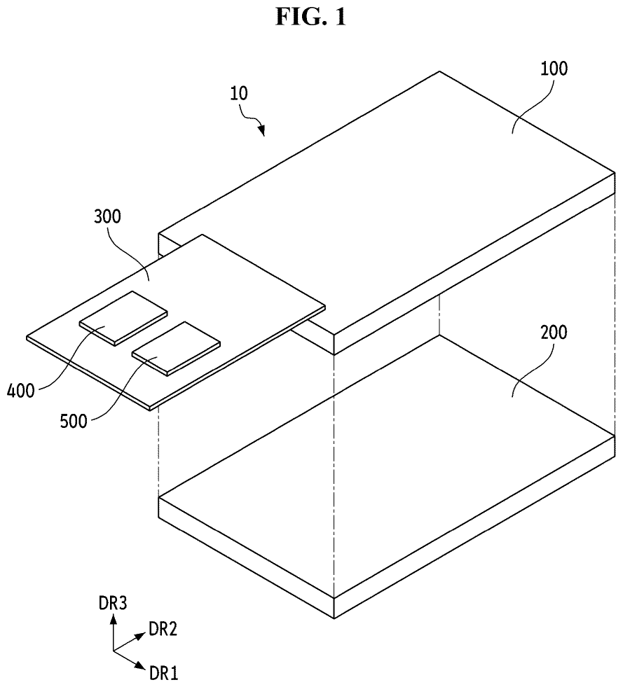

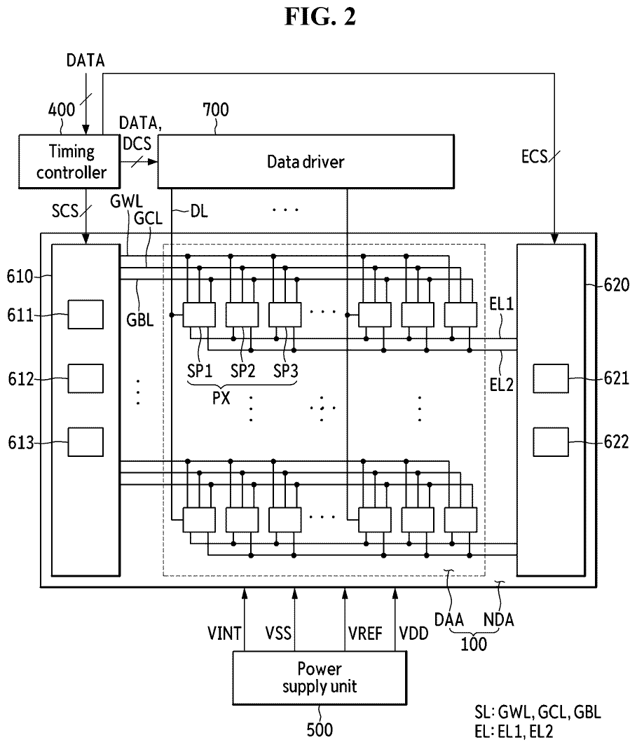

FIG. 1 is an exploded perspective view showing a display device according to one or more embodiments. FIG. 2 is a block diagram illustrating a display device according to one or more embodiments.

Referring to FIGS. 1 and 2, a display device 10 according to one or more embodiments is a device displaying a moving image and/or a still image. The display device 10 according to one or more embodiments may be applied to portable electronic devices, such as a mobile phone, a smartphone, a tablet personal computer, a mobile communication terminal, an electronic organizer, an electronic book, a portable multimedia player (PMP), a navigation system, an ultra mobile PC (UMPC) and/or the like. For example, the display device 10 according to one or more embodiments may be applied as a display unit of a television, a laptop, a monitor, a billboard, and/or an Internet-of-Things (IoT) terminal. In one or more embodiments, the display device 10 according to one or more embodiments may be applied to a smart watch, a watch phone, a head mounted display (HMD) for implementing virtual reality and augmented reality, and/or the like.

The display device 10 according to one or more embodiments includes a display panel 100, a heat dissipation layer 200, a circuit board 300, a timing controller 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a set or predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present disclosure is not limited thereto.

The display panel 100 includes a display area DAA displaying an image and a non-display area NDA not displaying an image as shown in FIG. 2.

The display area DAA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL includes a plurality of write scan lines GWL, a plurality of control scan lines GCL, and a plurality of bias scan lines GBL. The plurality of emission control lines EL include a plurality of first emission control lines EL1 and a plurality of second emission control lines EL2.

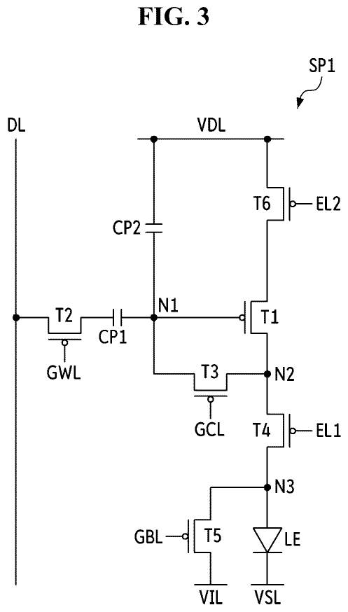

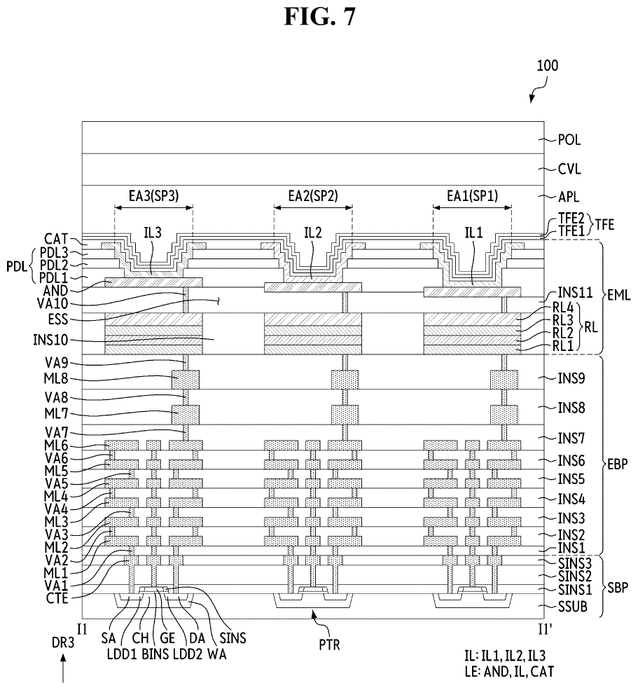

The plurality of pixels PX include (e.g., may each include) a plurality of sub-pixels (e.g., a first sub-pixel SP1, a second sub-pixel SP2, and a third sub-pixel SP3). The plurality of sub-pixels (e.g., the first sub-pixel SP1, the second sub-pixel SP2, and the third sub-pixel SP3) may include a plurality of pixel transistors as shown in FIG. 3, and the plurality of pixel transistors may be formed by a semiconductor process and arranged on (e.g., disposed on) a semiconductor substrate SSUB (see FIG. 7). For example, the plurality of pixel transistors of a data driver 700 may include (e.g., be formed of) complementary metal oxide semiconductor (CMOS).

Each of the plurality of sub-pixels (e.g., the first sub-pixel SP1, the second sub-pixel SP2, and the third sub-pixel SP3) may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and/or any one data line DL among the plurality of data lines DL. Each of the plurality of sub-pixels (e.g., the first sub-pixel SP1, the second sub-pixel SP2, and the third sub-pixel SP3) may receive a data voltage of the data line DL in response to a write scan signal of the write scan line GWL, and emit light from the light-emitting element according to the data voltage.

The non-display area NDA includes a scan driver 610, an emission driver 620, and the data driver 700.

The scan driver 610 includes a plurality of scan transistors, and the emission driver 620 includes a plurality of light-emitting transistors. The plurality of scan transistors and the plurality of light-emitting transistors may be on (e.g., formed/provided on) the semiconductor substrate SSUB (see FIG. 7) through a semiconductor process. For example, the plurality of scan transistors and the plurality of light-emitting transistors may include (e.g., be formed of) CMOS. Although it is illustrated in FIG. 2 that the scan driver 610 is arranged on (e.g., disposed on) the left side of the display area DAA and the emission driver 620 is arranged on (e.g., disposed on) the right side of the display area DAA, the present disclosure is not limited thereto. For example, the scan driver 610 and the emission driver 620 may be arranged on (e.g., disposed on) both (e.g., simultaneously) the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400 and output them sequentially (e.g., outputting the write scan signals in a serial order) to the write scan lines GWL. The control scan signal output unit 612 may generate control scan signals in response to the scan timing control signal SCS and sequentially output them (e.g., outputting the control scan signals in a serial order) to the control scan lines GCL. The bias scan signal output unit 613 may generate bias scan signals according to the scan timing control signal SCS and output them sequentially (e.g., output the bias scan signals in a serial order) to the bias scan lines GBL.

The emission driver 620 includes a first emission control driver 621 and a second emission control driver 622. Each of the first emission control driver 621 and the second emission control driver 622 may receive an emission timing control signal ECS from the timing controller 400. The first emission control driver 621 may generate first emission control signals according to the emission timing control signal ECS and sequentially output them (e.g., outputting the first emission control signals in a serial order) to the first emission control lines EL1. The second emission control driver 622 may generate second emission control signals according to the emission timing control signal ECS and sequentially output them (e.g., outputting the second emission control signals in a serial order) to the second emission control lines EL2.

The data driver 700 may include a plurality of data transistors, and the plurality of data transistors may be on (e.g., formed/provided on) the semiconductor substrate SSUB (see FIG. 7) through a semiconductor process. For example, the plurality of data transistors may include (e.g., be formed of) CMOS.

The data driver 700 may receive digital video data DATA and a data timing control signal DCS from the timing controller 400. The data driver 700 converts the digital video data DATA into analog data voltages according to the data timing control signal DCS, and outputs the analog data voltages to the data lines DL. In this case, the plurality of sub-pixels (e.g., the first sub-pixel SP1, the second sub-pixel SP2, and the third pixel SP3) may be selected by the write scan signal of the scan driver 610, and data voltages may be supplied to the selected plurality sub-pixels (e.g., the first sub-pixel SP1, the second sub-pixel SP2, and the third sub-pixel SP3).

The heat dissipation layer 200 may overlap the display panel 100 in a third direction DR3, which is the thickness direction of the display panel 100. The heat dissipation layer 200 may be arranged on (e.g., disposed on) one surface of the display panel 100, for example, on the rear surface of the display panel 100. The heat dissipation layer 200 serves to dissipate heat generated from the display panel 100. The heat dissipation layer 200 may include a metal layer, such as graphite, silver (Ag), copper (Cu), and/or aluminum (Al) having high thermal conductivity.

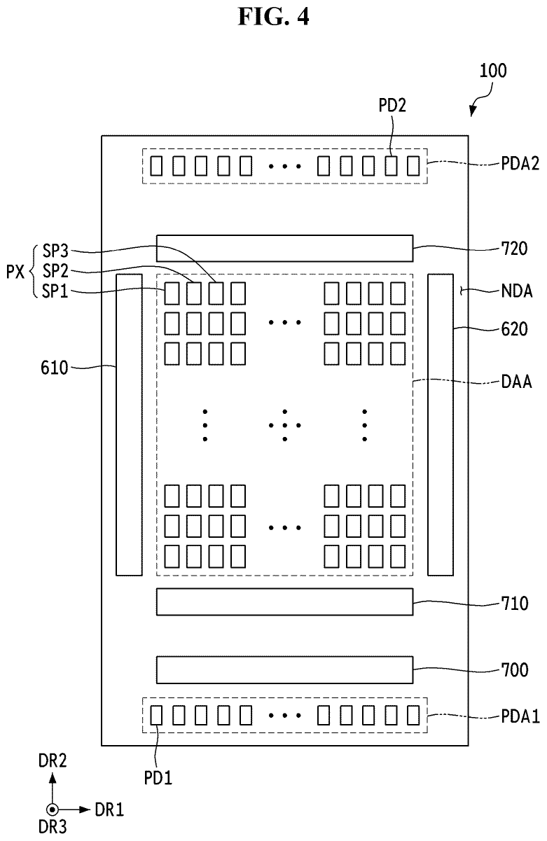

The circuit board 300 may be connected to (e.g., electrically connected to) a plurality of first pads PD1 (see FIG. 4) of a first pad portion PDA1 (see FIG. 4) of the display panel 100 by utilizing a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be arranged on (e.g., disposed on) the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by utilizing a conductive adhesive member.

The timing controller 400 may receive the digital video data DATA and timing signals inputted from the outside. The timing controller 400 may generate the scan timing control signal SCS, the emission timing control signal ECS, and the data timing control signal DCS for controlling the display panel 100 in response to the timing signals. The timing controller 400 may output the scan timing control signal SCS to the scan driver 610, and output the emission timing control signal ECS to the emission driver 620. The timing controller 400 may output the digital video data DATA and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT, and supply them (e.g., the first driving voltage VSS, the second driving voltage VDD, and the third driving voltage VINT) to the display panel 100. The first driving voltage VSS, the second driving voltage VDD, and the third driving voltage VINT will be described in more detail in conjunction with FIG. 3.

Each of the timing controller 400 and the power supply circuit 500 may be formed/provided as an integrated circuit (IC) and attached to one surface of the circuit board 300. In this case, the scan timing control signal SCS, the emission timing control signal ECS, the digital video data DATA, and the data timing control signal DCS of the timing controller 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In one or more embodiments, similarly to the scan driver 610, the emission driver 620, and the data driver 700, each of the timing controller 400 and the power supply circuit 500 may be arranged in (e.g., disposed in) the non-display area NDA of the display panel 100. In this case, the timing controller 400 may include a plurality of timing transistors, and the power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may include (e.g., be formed of) CMOS. Each of the timing controller 400 and the power supply circuit 500 may be arranged between (e.g., disposed between) the data driver 700 and the first pad portion PDA1 (see FIG. 4).

FIG. 3 is an equivalent circuit diagram of a first sub-pixel according to one or more embodiments.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 includes a plurality of transistors T1 to T6, a light-emitting element LE, a first capacitor CP1, and a second capacitor CP2.

The light-emitting element LE emits light in response to a source-drain current (hereinafter referred to as “driving current”) flowing through the channel of the first transistor T1. The emission amount of the light-emitting element LE may be proportional to the driving current. The light-emitting element LE may be arranged between (e.g., disposed between) a fourth transistor T4 and the first driving voltage line VSL. The first electrode of the light-emitting element LE may be connected to the drain electrode of the fourth transistor T4, and the second electrode of the light-emitting element LE may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer arranged between (e.g., disposed between) the first electrode and the second electrode, but the present disclosure is not limited thereto. For example, the light-emitting element LE may be an inorganic light-emitting element including a first electrode, a second electrode, and an inorganic semiconductor arranged between the first electrode and the second electrode, in which case the light-emitting element LE may be a micro light-emitting diode.

The first transistor T1 may be a driving transistor that controls the driving current flowing between the source electrode and the drain electrode thereof according to a voltage applied to the gate electrode thereof. The first transistor T1 includes a gate electrode connected to a first node N1, a source electrode connected to the drain electrode of a sixth transistor T6, and a drain electrode connected to a second node N2.

A second transistor T2 may be arranged between (e.g., disposed between) one electrode of the first capacitor CP1 and the data line DL. The second transistor T2 is turned on by the write scan signal of the write scan line GWL to connect one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

A third transistor T3 may be arranged between the first node N1 and the second node N2. The third transistor T3 is turned on by the write control signal of the write control line GCL to connect the first node N1 to the second node N2. In this case, because the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

A fifth transistor T5 may be arranged between (e.g., disposed between) the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 includes a gate electrode connected to the bias scan line GBL, a source electrode connected to the third node N3, and a drain electrode connected to the third driving voltage line VIL.

The sixth transistor T6 may be arranged between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type (kind) MOSFET, but the present disclosure is not limited thereto. Each of the first to sixth transistors T1 to T6 may be an N-type (kind) MOSFET. In one or more embodiments, some of the first to sixth transistors T1 to T6 may be P-type (kind) MOSFETs, and each of the remaining transistors may be an N-type (kind) MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating an example of a display panel according to one or more embodiments.

Referring to FIG. 4, the display area DAA of the display panel 100 according to one or more embodiments includes the plurality of pixels PX arranged in a matrix form. The non-display area NDA of the display panel 100 according to one or more embodiments includes the scan driver 610, the emission driver 620, the data driver 700, a first distribution circuit 710, a second distribution circuit 720, the first pad portion PDA1, and a second pad portion PDA2.

The scan driver 610 may be arranged on (e.g., disposed on) the first side of the display area DAA, and the emission driver 620 may be arranged on (e.g., disposed on) the second side of the display area DAA. For example, the scan driver 610 may be arranged on (e.g., disposed on) one side of the display area DAA in the first direction DR1, and the emission driver 620 may be arranged on (e.g., disposed on) the other side of the display area DAA in the first direction DR1 (e.g., the scan driver 610 and the emission driver 620 may be arranged on the opposite sides of the display area DAA respectively, such as the right side and the left side of the display area DAA, the front side and the rear side of the display area DAA, and/or the like). For example, the scan driver 610 may be arranged on the left side of the display area DAA, and the emission driver 620 may be arranged on (e.g., disposed on) the right side of the display area DAA. However, the present disclosure is not limited thereto, and the scan driver 610 and the emission driver 620 may be arranged on (e.g., disposed on) both (e.g., simultaneously) the first side and the second side of the display area DAA (e.g., the first side and the second side of the display area DAA are not necessarily opposite to each other).

The first pad portion PDA1 may include the plurality of first pads PD1 connected to pads or bumps of the circuit board 300 through a conductive adhesive member. The first pad portion PDA1 may be arranged on (e.g., disposed on) the third side of the display area DAA. For example, the first pad portion PDA1 may be arranged on (e.g., disposed on) one side of the display area DAA in the second direction DR2.

The first pad portion PDA1 may be arranged outside (e.g., disposed outside) the data driver 700 in the second direction DR2. For example, the first pad portion PDA1 may be arranged (e.g., disposed) closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig and/or a probe pin during an inspection process, or may be connected to a circuit board for inspection. The circuit board for inspection may be a printed circuit board made of a rigid material or a flexible printed circuit board made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P-th (P is a positive integer of 2 or more) data lines DL, and as a result, the number of the plurality of first pads PD1 may be reduced. The first distribution circuit 710 may be arranged on (e.g., disposed on) the third side of the display area DAA of the display panel 100. For example, the first distribution circuit 710 may be arranged on (e.g., disposed on) one side of the display area DAA in the second direction DR2. For example, the first distribution circuit 710 may be arranged on (e.g., disposed on) the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be arranged on (e.g., disposed on) the fourth side of the display area DAA of the display panel 100. For example, the second distribution circuit 720 may be arranged on (e.g., disposed on) the other side of the display area DAA in the second direction DR2. For example, the second distribution circuit 720 may be arranged on (e.g., disposed on) the upper side of the display area DAA.

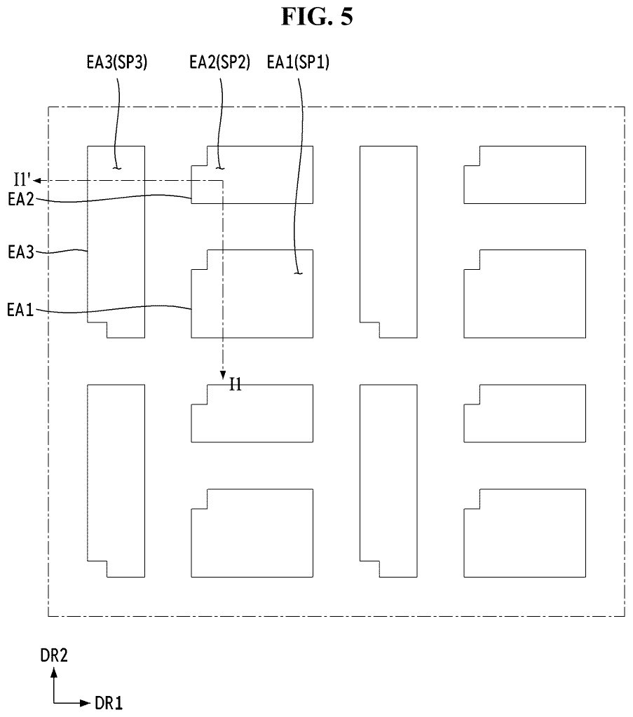

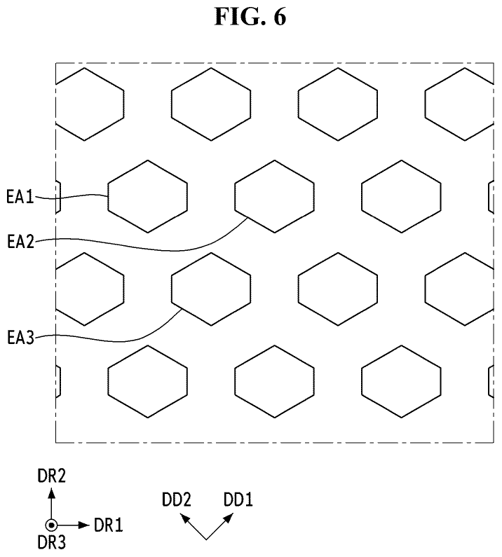

FIGS. 5 and 6 are each a layout diagram illustrating embodiments of the display area of FIG. 4.

Referring to FIGS. 5 and 6, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have a polygonal, circular, elliptical, and/or atypical shape in a plan view. In the context of the present disclosure and unless defined otherwise, a plan view refers to a top-down view of, e.g., the display panel layout, showing the arrangement of various components on a flat plane. For example, this view helps in understanding the spatial relationships and positions of the different elements within the display panel. In the context of FIG. 4, a plan view would show the layout of the display panel, including the arrangement of the display area DAA and the non-display area NDA components such as the scan driver, emission driver, data driver, distribution circuits, and pad portions, as seen from above. This view helps visualize how these components are positioned relative to each other on the display panel.

The maximum length of the third emission area EA3 in the first direction DR1 may be less than the maximum length of the first emission area EA1 in the first direction DR1 and the maximum length of the second emission area EA2 in the first direction DR1. The maximum length of the first emission area EA1 in the first direction DR1 and the maximum length of the second emission area EA2 in the first direction DR1 may be substantially the same.

The maximum length of the third emission area EA3 in the second direction DR2 may be greater than the maximum length of the first emission area EA1 in the second direction DR2 and the maximum length of the second emission area EA2 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may have, in a plan view, a hexagonal shape formed of six straight lines as shown in FIGS. 5 and 6, but the present disclosure is not limited thereto. The first emission area EA1, the second emission area EA2, and the third emission area EA3 may have a polygonal shape other than a hexagon, a circular shape, an elliptical shape, or an atypical shape in a plan view.

As shown in FIG. 5, in each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. In addition, the second emission area EA2 and the third emission area EA3 may be adjacent to each other in the first direction DR1. The area of the first emission area EA1, the area of the second emission area EA2, and the area of the third emission area EA3 may be different.

In one or more embodiments, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction normal (e.g., perpendicular) to the first diagonal direction DD1.

The first emission area EA1 may be to emit a first light, the second emission area EA2 may be to emit a second light, and the third emission area EA3 may be to emit a third light. Here, the first light may be light of a blue wavelength band, the second light may be light of a green wavelength band, and the third light may be light of a red wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

FIGS. 5 and 6 illustrate that each of the plurality of pixels PX includes three emission areas EA1, EA2, and EA3, but the present disclosure is not limited thereto. For example, each of the plurality of pixels PX may include four emission areas.

In addition, the layout of the emission areas of the plurality of pixels PX is not limited to those illustrated in FIGS. 5 and 6. For example, the emission areas of the plurality of pixels PX may be arranged in (e.g., disposed in) a stripe structure in which the emission areas are arranged in the first direction DR1, a PenTile® structure in which the emission areas are arranged in a diamond shape, and/or a hexagonal structure in which the emission areas having, in a plan view, a hexagonal shape are arranged as shown in FIG. 6.

FIG. 7 is a cross-sectional view illustrating an example of a display panel taken along the line I1-I1′ of FIG. 5.

Referring to FIG. 7, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, and/or a silicon-germanium substrate. The semiconductor substrate SSUB may be a substrate doped with a first type (kind) impurity. A plurality of well regions WA may be arranged on the top surface of the semiconductor substrate SSUB. The plurality of well regions WA may be regions doped with a second type (kind) impurity. The second type (kind) impurity may be different from the aforementioned first type (kind) impurity. For example, if (e.g., when) the first type (kind) impurity is a p-type (kind) impurity, the second type (kind) impurity may be an n-type (kind) impurity. In one or more embodiments, if (e.g., when) the first type (kind) impurity is an n-type (kind) impurity, the second type (kind) impurity may be a p-type (kind) impurity.

Each of the plurality of well regions WA includes a source region SA corresponding to the source electrode of the pixel transistor PTR, a drain region DA corresponding to the drain electrode thereof, and a channel region CH arranged between (e.g., disposed between) the source region SA and the drain region DA.

A lower insulating film BINS may be arranged between (e.g., disposed between) a gate electrode GE and the well region WA. A side insulating film SINS may be arranged on (e.g., disposed on) the side surface of the gate electrode GE. The side insulating film SINS may be arranged on (e.g., disposed on) the lower insulating film BINS.

Each of the source region SA and the drain region DA may be a region doped with the first type (kind) impurity. The gate electrode GE of the pixel transistor PTR may overlap the well region WA in the third direction DR3. The channel region CH may overlap the gate electrode GE in the third direction DR3. The source region SA may be arranged on (e.g., disposed on) one side of the gate electrode GE, and the drain region DA may be arranged on (e.g., disposed on) the other side of the gate electrode GE.

Each of the plurality of well regions WA further includes a first low-concentration impurity region LDD1 arranged between (e.g., disposed between) the channel region CH and the source region SA, and a second low-concentration impurity region LDD2 arranged between (e.g., disposed between) the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating film SINS1 may be arranged on (e.g., disposed on) the semiconductor substrate SSUB. The first semiconductor insulating film SINS1 may include (e.g., be formed of) silicon carbonitride (SiCN) and/or a silicon oxide (SiOₓ)-based inorganic film, but the present disclosure is not limited thereto.

A second semiconductor insulating film SINS2 may be arranged on (e.g., disposed on) the first semiconductor insulating film SINS1. The second semiconductor insulating film SINS2 may include (e.g., be formed of) a silicon oxide (SiOₓ)-based inorganic film, but the present disclosure is not limited thereto.

The plurality of contact terminals CTE may be arranged on (e.g., disposed on) the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film INS2. The plurality of contact terminals CTE may include (e.g., be formed of) any one of copper (Cu), aluminum (AI), tungsten (W), molybdenum (Mo), chromium (Cr), gold (Au), titanium (Ti), nickel (Ni), and neodymium (Nd), and/or an alloy including any one of them.

A third semiconductor insulating film SINS3 may be arranged on (e.g., disposed on) a side surface of each of the plurality of contact terminals CTE. The top surface of each of the plurality of contact terminals CTE may be exposed without being covered by the third semiconductor insulating film SINS3. The third semiconductor insulating film SINS3 may include (e.g., be formed of) a silicon oxide (SiOₓ)-based inorganic film, but the present disclosure is not limited thereto.

The semiconductor substrate SSUB may be replaced with a glass substrate and/or a polymer resin substrate such as polyimide. In this case, thin film transistors may be arranged on (e.g., disposed on) the glass substrate and/or the polymer resin substrate. The glass substrate may be a rigid substrate that does not bend, and the polymer resin substrate may be a flexible substrate that may be bent or curved.

The light-emitting element backplane EBP includes a plurality of conductive layers ML1 to ML8, a plurality of vias VA1 to VA9, and a plurality of insulating films INS1 to INS9. In addition, the light-emitting element backplane EBP includes a plurality of insulating films INS1 to INS9 arranged between (e.g., disposed between) the contact terminal CTE and the reflective electrode layer RL.

The first to eighth conductive layers ML1 to ML8 serve to connect the plurality of contact terminals CTE exposed from the semiconductor backplane SBP to thereby implement the circuit of the first sub-pixel SP1 shown in FIG. 3. For example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and the first electrode of the light-emitting element LE is also accomplished through the first to eighth conductive layers ML1 to ML8.

The first insulating film INS1 may be arranged on (e.g., disposed on) the semiconductor backplane SBP. Each of the first vias VA1 may penetrate the first insulating film INS1 and be connected to the contact terminal CTE exposed from the semiconductor backplane SBP. Each of the first conductive layers ML1 may be arranged on (e.g., disposed on) the first insulating film INS1 and may be connected to the first via VA1.

The second insulating film INS2 may be arranged on (e.g., disposed on) the first insulating film INS1 and the first conductive layers ML1. Each of the second vias VA2 may penetrate the second insulating film INS2 and be connected to the exposed first conductive layer ML1. Each of the second conductive layers ML2 may be arranged on (e.g., disposed on) the second insulating film INS2 and may be connected to the second via VA2.

The third insulating film INS3 may be arranged on (e.g., disposed on) the second insulating film INS2 and the second conductive layers ML2. Each of the third vias VA3 may penetrate the third insulating film INS3 and be connected to the exposed second conductive layer ML2. Each of the third conductive layers ML3 may be arranged on (e.g., disposed on) the third insulating film INS3 and may be connected to the third via VA3.

A fourth insulating film INS4 may be arranged on (e.g., disposed on) the third insulating film INS3 and the third conductive layers ML3. Each of the fourth vias VA4 may penetrate the fourth insulating film INS4 and be connected to the exposed third conductive layer ML3. Each of the fourth conductive layers ML4 may be arranged on (e.g., disposed on) the fourth insulating film INS4 and may be connected to the fourth via VA4.

A fifth insulating film INS5 may be arranged on (e.g., disposed on) the fourth insulating film INS4 and the fourth conductive layers ML4. Each of the fifth vias VA5 may penetrate the fifth insulating film INS5 and be connected to the exposed fourth conductive layer ML4. Each of the fifth conductive layers ML5 may be arranged on (e.g., disposed on) the fifth insulating film INS5 and may be connected to the fifth via VA5.

A sixth insulating film INS6 may be arranged on (e.g., disposed on) the fifth insulating film INS5 and the fifth conductive layers ML5. Each of the sixth vias VA6 may penetrate the sixth insulating film INS6 and be connected to the exposed fifth conductive layer ML5. Each of the sixth conductive layers ML6 may be arranged on (e.g., disposed on) the sixth insulating film INS6 and may be connected to the sixth via VA6.

A seventh insulating film INS7 may be arranged on (e.g., disposed on) the sixth insulating film INS6 and the sixth conductive layers ML6. Each of the seventh vias VA7 may penetrate the seventh insulating film INS7 and be connected to the exposed sixth conductive layer ML6. Each of the seventh conductive layers ML7 may be arranged on (e.g., disposed on) the seventh insulating film INS7 and may be connected to the seventh via VA7.

An eighth insulating film INS8 may be arranged on (e.g., disposed on) the seventh insulating film INS7 and the seventh conductive layers ML7. Each of the eighth vias VA8 may penetrate the eighth insulating film INS8 and be connected to the exposed seventh conductive layer ML7. Each of the eighth conductive layers ML8 may be arranged on (e.g., disposed on) the eighth insulating film INS8 and may be connected to the eighth via VA8.

The first to eighth conductive layers ML1 to ML8 and the first to eighth vias VA1 to VA8 may include (e.g., be formed of) substantially the same material. The first to eighth conductive layers ML1 to ML8 and the first to eighth vias VA1 to VA8 may include (e.g., be formed of) any one of copper (Cu), aluminum (Al), tungsten (W), molybdenum (Mo), chromium (Cr), gold (Au), titanium (Ti), nickel (Ni), neodymium (Nd), and/or an alloy including any one of them. The first to eighth vias VA1 to VA8 may include (e.g., be made of) substantially the same material. First to eighth insulating films INS1 to INS8 may include (e.g., be formed of) a silicon oxide (SiOₓ)-based inorganic film, but the present disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via

VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating film INS9 may be arranged on (e.g., disposed on) the eighth insulating film INS8 and the eighth conductive layer ML8. The ninth insulating film INS9 may include (e.g., be formed of) a silicon oxide (SiOₓ)-based inorganic film, but the present disclosure is not limited thereto.

Each of the ninth vias VA9 may penetrate the ninth insulating film INS9 and be connected to the exposed eighth conductive layer ML8. The ninth vias VA9 may include (e.g., be formed of) any one of copper (Cu), aluminum (AI), tungsten (W), molybdenum (Mo), chromium (Cr), gold (Au), titanium (Ti), nickel (Ni), neodymium (Nd), and/or an alloy including any one of them. The thickness of the ninth via VA9 may be approximately 16500 Å.

The display element layer EML may be arranged on (e.g., disposed on) the light-emitting element backplane EBP. The display element layer EML may include light-emitting elements LE each including a reflective electrode layer RL, tenth and eleventh insulating films INS10 and INS11, a tenth via VA10, the first electrode AND, a light-emitting stack IL, and a second electrode CAT; and a pixel defining film PDL.

The reflective electrode layer RL may be arranged on (e.g., disposed on) the ninth insulating film INS9. The reflective electrode layer RL may include at least one reflective electrode RL1, RL2, RL3, and/or RL4. For example, the reflective electrode layer RL may include first to fourth reflective electrodes RL1, RL2, RL3, and RL4 as shown in FIG. 7.

Each of the first reflective electrodes RL1 may be arranged on (e.g., disposed on) the ninth insulating film INS9, and may be connected to the ninth via VA9. The first reflective electrodes RL1 may include (e.g., be formed of) any one of copper (Cu), aluminum (AI), tungsten (W), molybdenum (Mo), chromium (Cr), gold (Au), titanium (Ti), nickel (Ni), neodymium (Nd), and/or an alloy including any one of them. For example, the first reflective electrodes RL1 may include titanium nitride (TiN).

Each of the second reflective electrodes RL2 may be arranged on (e.g., disposed on) the first reflective electrode RL1. The second reflective electrodes RL2 may include (e.g., be formed of) any one of copper (Cu), aluminum (Al), tungsten (W), molybdenum (Mo), chromium (Cr), gold (Au), titanium (Ti), nickel (Ni), neodymium (Nd), and/or an alloy including any one of them. For example, the second reflective electrodes RL2 may include aluminum (Al).

Each of the third reflective electrodes RL3 may be arranged on (e.g., disposed on) the second reflective electrode RL2. The third reflective electrodes RL3 may include (e.g., be formed of) any one of copper (Cu), aluminum (AI), tungsten (W), molybdenum (Mo), chromium (Cr), gold (Au), titanium (Ti), nickel (Ni), neodymium

(Nd), and/or an alloy including any one of them. For example, the third reflective electrodes RL3 may include titanium nitride (TiN).

Each of the fourth reflective electrodes RL4 may be arranged on (e.g., disposed on) the third reflective electrode RL3. The fourth reflective electrodes RL4 may include (e.g., be formed of) any one of copper (Cu), aluminum (AI), tungsten (W), molybdenum (Mo), chromium (Cr), gold (Au), titanium (Ti), nickel (Ni), neodymium (Nd), and/or an alloy including any one of them. For example, the fourth reflective electrodes RL4 may include titanium (Ti).

Because the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be approximately 850 Å.

The tenth insulating film INS10 may be arranged on (e.g., disposed on) the ninth insulating film INS9. The tenth insulating film INS10 may be arranged between (e.g., disposed between) the reflective electrode layers RL adjacent to each other in a horizontal direction. The tenth insulating film INS10 may include (e.g., be formed of) a silicon oxide (SiOₓ)-based inorganic film, but the present disclosure is not limited thereto.

The eleventh insulating film INS11 may be arranged on (e.g., disposed on) the tenth insulating film INS10 and the reflective electrode layer RL. The eleventh insulating film INS11 may include (e.g., be formed of) a silicon oxide (SiOₓ)-based inorganic film, but the present disclosure is not limited thereto. The tenth insulating film INS10 and the eleventh insulating film INS11 may be an optical auxiliary layer through which light reflected by the reflective electrode layer RL passes, among light emitted from the light-emitting elements LE.

In order to match the resonance distance of the light emitted from the light-emitting elements LE in at least one of the first sub-pixel SP1, the second sub-pixel SP2, and/or the third sub-pixel SP3, the tenth insulating film INS10 or the eleventh insulating film INS11 may not be arranged under (e.g., disposed under) the first electrode AND. For example, the first electrode AND of the first sub-pixel SP1 may be directly arranged on (e.g., disposed on) the reflective electrode layer RL. The eleventh insulating film INS11 may be arranged under (e.g., disposed under) the first electrode AND of the second sub-pixel SP2. The tenth insulating film INS10 and the eleventh insulating film INS11 may be arranged under (e.g., disposed under) the first electrode AND of the third sub-pixel SP3.

In summary, the distance between the first electrode AND and the reflective electrode layer RL may be different in the first sub-pixel SP1, the second sub-pixel SP2, and the third sub-pixel SP3. For example, in order to adjust the distance from the reflective electrode layer RL to the first electrode AND according to the main wavelength of the light emitted from each of the first sub-pixel SP1, the second sub-pixel SP2, and the third sub-pixel SP3, the presence or absence of the tenth insulating film INS10 and the eleventh insulating film INS11 may be set in each of the first sub-pixel SP1, the second sub-pixel SP2, and the third sub-pixel SP3. For example, the distance between the first electrode AND and the reflective electrode layer RL in the third sub-pixel SP3 may be greater than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 may be greater than the distance between the first electrode AND and the reflective electrode layer RL in the first sub-pixel SP1. The present disclosure is not limited to the above examples.

In addition, although the tenth insulating film INS10 and the eleventh insulating film INS11 are illustrated in the present disclosure, a twelfth insulating film arranged under (e.g., disposed under) the first electrode AND of the first sub-pixel SP1 may be added. In this case, the eleventh insulating film INS11 and the twelfth insulating film may be arranged under (e.g., disposed under) the first electrode AND of the second sub-pixel SP2, and the tenth insulating film INS10, the eleventh insulating film INS11, and the twelfth insulating film may be arranged under (e.g., disposed under) the first electrode AND of the third sub-pixel SP3.

Each of the tenth vias VA10 may penetrate the tenth insulating film INS10 and/or the eleventh insulating film INS11 in the second sub-pixel SP2 and the third sub-pixel SP3 and may be connected to the exposed fourth reflective electrode RL4. The tenth vias VA10 may include (e.g., be formed of) any one of copper (Cu), aluminum (AI), tungsten (W), molybdenum (Mo), chromium (Cr), gold (Au), titanium (Ti), nickel (Ni), neodymium (Nd), and/or an alloy including any one of them. The thickness of the tenth via VA10 in the second sub-pixel SP2 may be less than the thickness of the tenth via VA10 in the third sub-pixel SP3.

The first electrode AND of each of the light-emitting elements LE may be arranged on (e.g., disposed on) the tenth insulating film INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements

LE may include (e.g., be formed of) any one of copper (Cu), aluminum (AI), tungsten (W), molybdenum (Mo), chromium (Cr), gold (Au), titanium (Ti), nickel (Ni), neodymium (Nd), and/or an alloy including any one of them. For example, the first electrode AND of each of the light-emitting elements LE may be titanium nitride (TiN).

The pixel defining film PDL may be arranged on (e.g., disposed on) a portion of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3.

The first emission area EA1 may be defined as an area, in which the first electrode AND, the light-emitting stack IL, and the second electrode CAT are sequentially stacked in the first sub-pixel SP1 to emit light. The second emission area EA2 may be defined as an area, in which the first electrode AND, the light-emitting stack IL, and the second electrode CAT are sequentially stacked in the second sub-pixel SP2 to emit light. The third emission area EA3 may be defined as an area, in which the first electrode AND, the light-emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be arranged on (e.g., disposed on) the edge of the first electrode AND of each of the light-emitting elements LE, the second pixel defining film PDL2 may be arranged on (e.g., disposed on) the first pixel defining film PDL1, and the third pixel defining film PDL3 may be arranged on (e.g., disposed on) the second pixel defining film PDL2. The first pixel defining film PDL1, the second pixel defining film PDL2, and the third pixel defining film PDL3 may include (e.g., be formed of) a silicon oxide (SiOₓ)-based inorganic film, but the present disclosure is not limited thereto. The first pixel defining film PDL1, the second pixel defining film PDL2, and the third pixel defining film PDL3 may each have a thickness of about 500 Å.

If (e.g., when) the first pixel defining film PDL1, the second pixel defining film PDL2, and the third pixel defining film PDL3 are provided as (e.g., formed as) one pixel defining film, the height of the one pixel defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 and the second direction DR2.

The light-emitting stack IL may include a plurality of intermediate layers. The light-emitting stack IL includes a first stack layer IL1, a second stack layer IL2, and a third stack layer IL3 that emit different lights. The first stack layer IL1, the second stack layer IL2, and the third stack layer IL3 are discontinuous between adjacent sub-pixels. For example, the first stack layer IL1, the second stack layer IL2, and the third stack layer IL3 are not in a direct contact with each other as shown in FIG. 7.

The first stack layer IL1 may have a structure, in which a first hole transport layer, a first organic light-emitting layer that emits the first light, and a first electron transport layer are sequentially stacked. The first stack layer IL1 is arranged on (e.g., disposed on) the first electrodes AND and the pixel defining film PDL in the first emission area EA1 of the first sub-pixel SP1.

The second stack layer IL2 may have a structure, in which a second hole transport layer, a second organic light-emitting layer that emits the third light, and a second electron transport layer are sequentially stacked. The second stack layer IL2 is arranged on (e.g., disposed on) the first electrodes AND and the pixel defining film PDL in the second emission area EA2 of the second sub-pixel SP2.

The third stack layer IL3 may have a structure, in which a third hole transport layer, a third organic light-emitting layer that emits the second light, and a third electron transport layer are sequentially stacked. The third stack layer IL3 is arranged on (e.g., disposed on) the first electrodes AND and the pixel defining film PDL in the third emission area EA3 of the third sub-pixel SP3.

The second electrode CAT may be arranged on (e.g., disposed on) the third stack layer IL3 and the pixel defining film PDL. The second electrode CAT may include (e.g., be formed of) a transparent conductive material (TCO) such as indium tin oxide (ITO) and/or indium zinc oxide (IZO) that may transmit light or a semi-transmissive conductive material such as magnesium (Mg), silver (Ag), and/or an alloy of Mg and Ag. If (e.g., when) the second electrode CAT includes (e.g., is formed of) a semi-transmissive conductive material, the light emission efficiency may be improved in each of the first to third sub-pixels SP1, SP2, and SP3 due to a micro-cavity effect.

The encapsulation layer TFE may be arranged on (e.g., disposed on) the display element layer EML. The encapsulation layer TFE may include at least one inorganic film TFE1 and TFE2 to reduce or prevent oxygen or moisture from permeating into the display element layer EML. For example, the encapsulation layer TFE may include the first encapsulation inorganic film TFE1, and a second encapsulation inorganic film TFE2.

The first encapsulation inorganic film TFE1 may be arranged on (e.g., disposed on) the second electrode CAT. The first encapsulation inorganic film TFE1 may be provided as (e.g., formed as) a multilayer, in which one or more inorganic films selected from among silicon nitride (SiNₓ), silicon oxy nitride (SiON), and/or silicon oxide (SiOₓ) are alternately stacked. The first encapsulation inorganic film TFE1 may be provided by (e.g., formed by) a chemical vapor deposition (CVD) process.

The second encapsulation inorganic film TFE2 may be arranged on (e.g., disposed on) the first encapsulation inorganic film TFE1. The second encapsulation inorganic film TFE2 may include (e.g., be formed of) titanium oxide (TiOₓ) and/or aluminum oxide (AlOₓ), but the present disclosure is not limited thereto. The second encapsulation inorganic film TFE2 may be provided by (e.g., formed by) an atomic layer deposition (ALD) process. The thickness of the second encapsulation inorganic film TFE2 may be less than the thickness of the first encapsulation inorganic film TFE1.

An organic film APL may be a layer for increasing the interfacial adhesion between the encapsulation layer TFE and the cover layer CVL. The organic film APL may be an organic film, such as acrylic resin, epoxy resin, phenolic resin, polyamide resin, and/or polyimide resin.

The cover layer CVL may be arranged on (e.g., disposed on) the organic film APL. The cover layer CVL may be a glass substrate and/or a polymer resin.

The polarizing plate POL may be arranged on (e.g., disposed on) one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the present disclosure is not limited thereto.

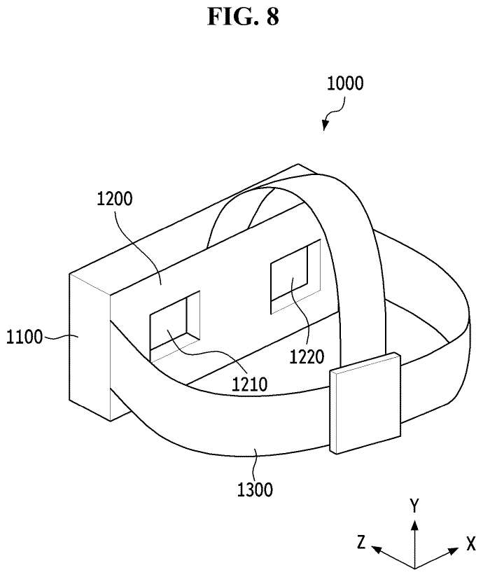

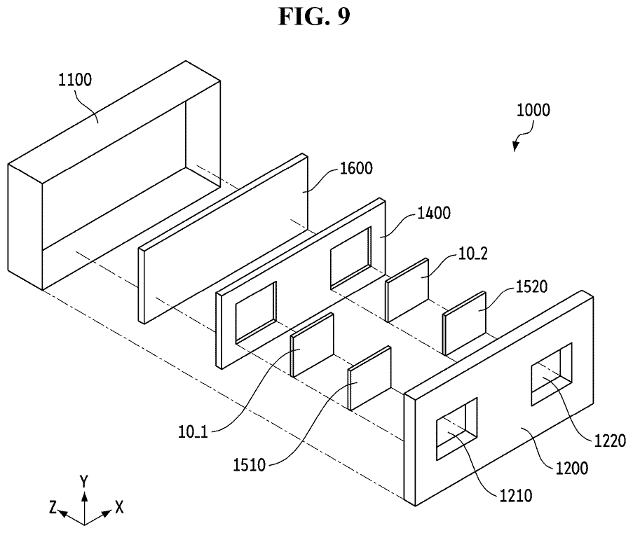

FIG. 8 is a perspective view illustrating a head mounted display according to one or more embodiments. FIG. 9 is an exploded perspective view illustrating an example of the head mounted display of FIG. 8.

Referring to FIGS. 8 and 9, a head mounted display 1000 according to one or more embodiments includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is substantially the same as the display device 10 described in conjunction with FIGS. 1 and 2, description of the first display device 10_1 and the second display device 10_2 will not be provided.

The first optical member 1510 may be arranged between (e.g., disposed between) the first display device 10_1 and the first eyepiece 1210. The second optical member 1520 may be arranged between (e.g., disposed between) the second display device 10_2 and the second eyepiece 1220. Each of the first optical member 1510 and the second optical member 1520 may include at least one convex lens.

The middle frame 1400 may be arranged between (e.g., disposed between) the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be arranged between (e.g., disposed between) the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may be to transmit the digital video data DATA corresponding to a left-eye image improved or optimized for the user's left eye to the first display device 10_1, and may be to transmit the digital video data DATA corresponding to a right-eye image improved or optimized for the user's right eye to the second display device 10_2. In one or more embodiments, the control circuit board 1600 may be to transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is arranged to cover one open surface of the display device housing 1100. The housing cover 1200 may include the first eyepiece 1210 at which the user's left eye is located and the second eyepiece 1220 at which the user's right eye is located. FIGS. 8 and 9 illustrate that the first eyepiece 1210 and the second eyepiece 1220 are arranged separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

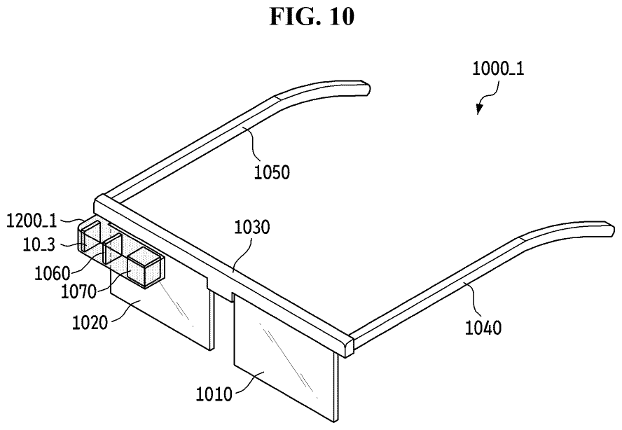

The head mounted band 1300 serves to secure the display device housing 1100 to the user's head such that the first eyepiece 1210 and the second eyepiece 1220 of the housing cover 1200 remain located on the user's left and right eyes, respectively. If (e.g., when) the display device housing 1200 is implemented to be lightweight and compact, the head mounted display 1000 may be provided with, as shown in FIG. 10, an eyeglass frame instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, and/or a high-definition multimedia interface (HDMI) terminal, and the wireless communication module may be a 5G communication module, a 4G communication module, a Wi-Fi module, and/or a Bluetooth module.

FIG. 10 is a perspective view illustrating a head mounted display according to one or more embodiments.

Referring to FIG. 10, a head mounted display 1000_1 according to one or more embodiments may be an eyeglasses-type (kind) display device in which a display device housing 1200_1 is implemented in a lightweight and compact manner. The head mounted display 1000_1 according to one or more embodiments may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 10 illustrates that the display device housing 1200_1 is arranged at the right end of the support frame 1030, but the present disclosure is not limited thereto. For example, the display device housing 1200_1 may be arranged at the left end of the support frame 1030, and in this case, the image of the display device 10_3 may be provided to the user's left eye. In one or more embodiments, the display device housing 1200_1 may be arranged at both (e.g., simultaneously) the left and right ends of the support frame 1030, and in this case, the user may view the image displayed on the display device 10_3 through both (e.g., simultaneously) the left and right eyes.

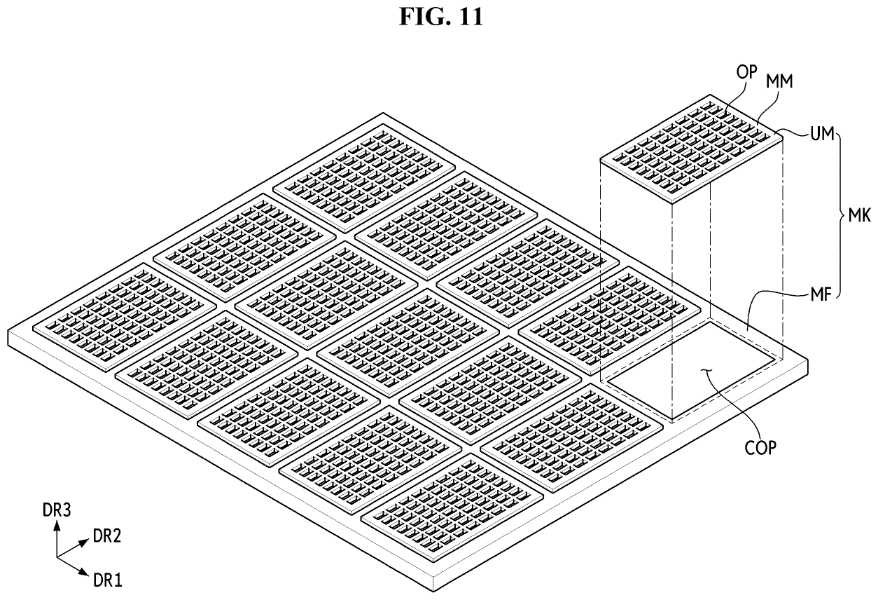

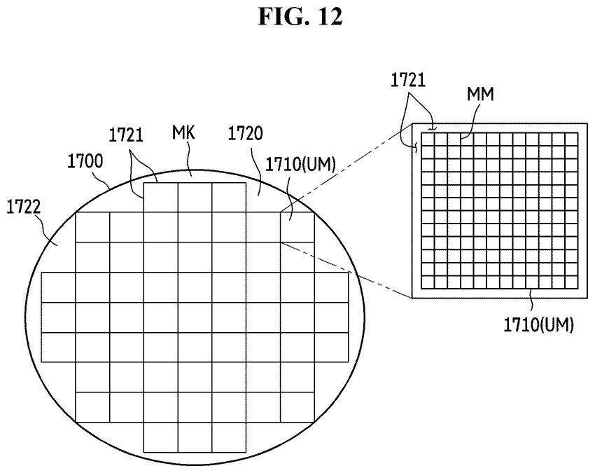

FIG. 11 is a perspective view of a mask according to one or more embodiments. FIG. 12 is a schematic plan view of a mask according to one or more embodiments. FIG. 11 shows a perspective view of a state in which one unit mask UM is separated from a plurality of unit masks. The mask according to one or more embodiments shown in FIGS. 11 and 12 may be used in the process of depositing at least a portion of the light-emitting stack IL described with reference to FIG. 7. For example, the light-emitting stack IL may be configured to emit a different color in each of the sub-pixels SP1, SP2, and SP3.

Referring to FIGS. 11 and 12, a mask MK according to one or more embodiments may be a shadow mask in which a mask membrane MM is arranged on a silicon substrate 1700. The mask MK according to one or more embodiments may be referred to as “silicon mask.”

According to one or more embodiments, the mask MK may include the silicon substrate 1700, and the mask membrane MM may be arranged on (e.g., disposed on) the silicon substrate 1700. The mask membrane MM may be arranged in (e.g., disposed in) cell regions 1710 arranged in a matrix form, and each cell region 1710 may be surrounded by a mask lip region 1721. The mask lip region 1721 may have a portion of the silicon substrate arranged (e.g., disposed) therein, and may serve to support the mask membrane MM.

The mask membrane MM may be a portion of the unit mask UM arranged in (e.g., disposed in) each of the plurality of cell regions 1710.

The silicon substrate 1700 may include the plurality of cell regions 1710 and a mask frame region 1720 excluding the plurality of cell regions 1710. The mask frame region 1720 may include the mask lip region 1721 around (e.g., surrounding) each cell region 1710, and an outer frame region 1722 arranged at (e.g., disposed at) the outermost edge of the silicon substrate 1700. A mask frame MF may be arranged in (e.g., disposed in) the mask frame region 1720, and the mask frame MF may include a mask lip around (e.g., surrounding) the cell region 1710.

The mask lip region 1721 may be a region that partitions the plurality of cell regions 1710. For example, the plurality of cell regions 1710 may be arranged in a matrix form, and the mask lip arranged in (e.g., disposed in) the mask lip region 1721 may be arranged (e.g., disposed) to be around (e.g., surround) the outer edge of the mask membrane MM arranged in (e.g., disposed in) each cell region 1710.

A cell opening COP and the unit mask UM for masking at least a portion of the cell opening COP may be arranged in (e.g., disposed in) each of the plurality of cell regions 1710 of the silicon substrate 1700.

The plurality of cell openings COP may penetrate the mask frame MF along a thickness direction (e.g., the third direction DR3) of the mask MK. The plurality of cell openings COP may be provided by (e.g., formed by) etching a portion of the silicon substrate 1700 from the rear direction.

Each unit mask UM may include the mask membrane MM, and the mask membrane MM may include a mask opening.

The mask opening of the mask membrane MM may be referred to as “hole” or “mask hole.” The mask openings may penetrate the unit masks UM along the thickness direction (e.g., the third direction DR3) of the mask MK.

One unit mask UM may be utilized in the deposition process of one display panel 100. In the present disclosure, the term “unit mask UM” may be replaced with a term such as a mask unit UM.

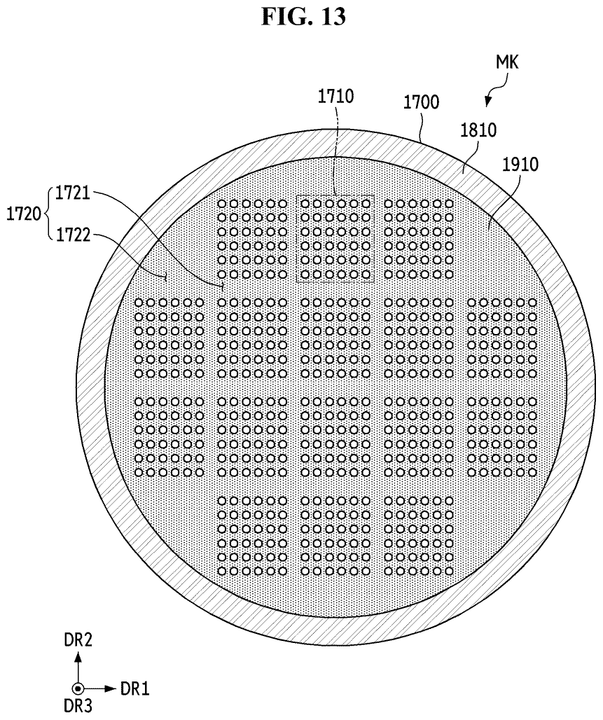

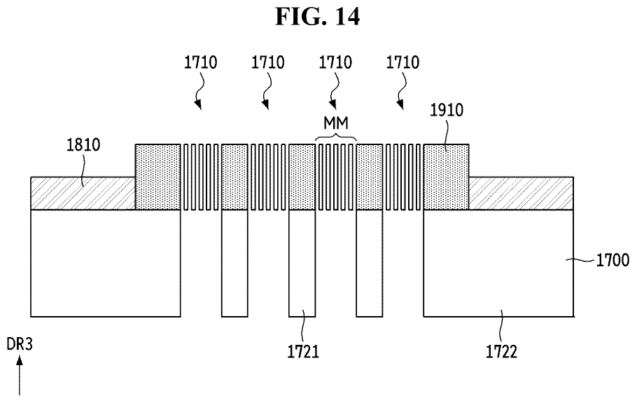

FIG. 13 is a schematic plan view of a mask according to a comparative example. FIG. 14 is a cross-sectional view of the mask shown in FIG. 13.

Referring to FIGS. 13 and 14, the mask MK according to a comparative example includes the substrate 1700 (e.g., 1700 of FIG. 12), and an inorganic film 1910 is arranged on (e.g., disposed on) the substrate 1700.

At least a portion of the inorganic film 1910 is patterned in each of the plurality of cell regions 1710 to form the mask membrane MM. For example, the inorganic film 1910 may be a first type (kind) inorganic film 1910, which is a material that exerts tensile stress on the substrate 1700, or a second type (kind) inorganic film 1910, which is a material that exerts compressive stress on the substrate 1700.

In the comparative example of FIGS. 13 and 14, the description will focus on the case where the inorganic film 1910 is the first type (kind) inorganic film 1910, which is a material that exerts tensile stress on the substrate 1700. For example, the inorganic film 1910 may include silicon nitride (SiNₓ), and silicon nitride (SiNₓ) may be a material that exerts tensile stress on the substrate 1700 after being deposited on the substrate 1700.

The mask membrane MM may include the inorganic film 1910 and the plurality of mask openings. The mask membrane MM may be exposed from the rear surface of the substrate 1700 through the cell opening COP (see FIG. 11) provided by (e.g., formed by) etching the rear surface of the substrate 1700.

Around the plurality of cell regions 1710, the mask lip region 1721 is arranged to be around (e.g., surround) each cell region. In addition, the outer frame region 1722 is arranged outside the entire plurality of cell regions 1710. The inorganic film 1910 (e.g., a dummy inorganic film) that remains not patterned is arranged in the mask lip region 1721 and a portion of the outer frame region 1722.

In the outer frame region 1722, at least one alignment key for aligning the mask MK is arranged outside the inorganic film 1910. For example, the alignment key may be a first metal, which is a material that exerts tensile stress on the substrate 1700, or a second metal, which is a material that exerts compressive stress on the substrate 1700.

In the comparative example of FIGS. 13 and 14, the description will focus on the case where a metal 1810 for forming the alignment key has a property opposite to that of the inorganic film 1910. For example, the inorganic film 1910 may be a material that exerts tensile stress on the substrate 1700 after being deposited on the substrate 1700, whereas the metal 1810 for forming the alignment key may be a material that exerts compressive stress on the substrate 1700, contrary to the inorganic film 1910.

The metal 1810 having a property (e.g., a material that exerts compressive stress on the substrate 1700) opposite to the property (e.g., a material that exerts tensile stress on the substrate 1700) of the inorganic film 1910 is arranged in the outer frame region 1722 located at the outer edge of the substrate 1700. The metal 1810 may exert compressive stress on the substrate 1700 while being arranged to be around (e.g., surround) the entire outer edge portion of the substrate 1700.

As in the comparative example of FIGS. 13 and 14, if (e.g., when) the metal 1810 having a property (e.g., a material that exerts compressive stress on the substrate 1700) opposite to the property (e.g., a material that exerts tensile stress on the substrate 1700) of the inorganic film 1910 is arranged at the outer edge of the substrate 1700, the bending of the substrate 1700 increases. For example, if (e.g., when) the metal 1810 having a property (e.g., a material that exerts compressive stress on the substrate 1700) opposite to the property (e.g., a material that exerts tensile stress on the substrate 1700) of the inorganic film 1910 is arranged at the outer edge of the substrate 1700, a warpage value, which is a parameter indicating the bending characteristics of the substrate 1700, increases.

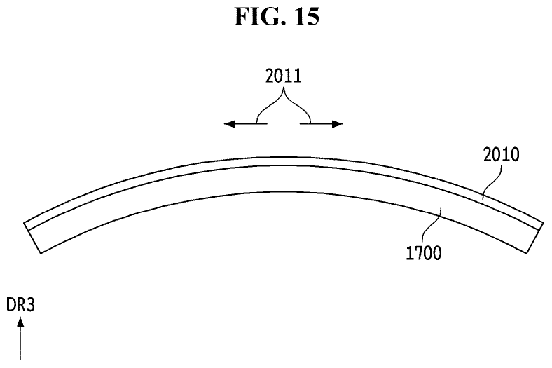

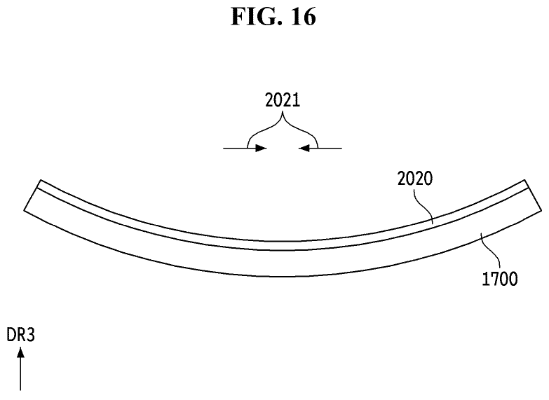

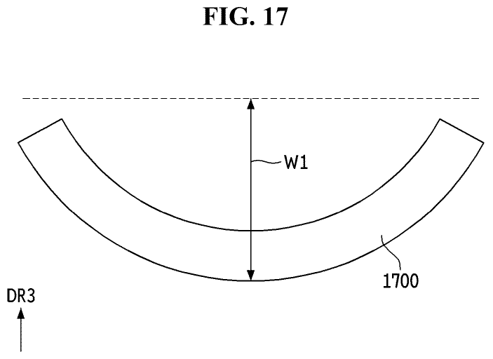

FIGS. 15 and 16 are each a conceptual diagram illustrating stress exerted on a substrate by a thin film deposited on the substrate. FIG. 17 is a conceptual diagram illustrating a warpage of the mask shown in FIG. 13.

Referring to FIG. 15, a thin film 2010 deposited on the substrate 1700 (e.g., 1700 of FIG. 17) may be a material that exerts compressive stress 2011 on the substrate 1700. For example, during the process of depositing the thin film 2010 on the substrate 1700 and patterning the deposited thin film 2010, a deviation in the coefficient of thermal expansion (CTE) between the substrate 1700 and the thin film 2010 occurs. This deviation in the coefficient of thermal expansion causes the thin film 2010 to exert the compressive stress 2011 on the substrate 1700, which increases the bending and warpage value of the substrate 1700

Referring to FIG. 16, a thin film 2020 deposited on the substrate 1700 (e.g., 1700 of FIG. 17) may be a material that exerts tensile stress 2021 on the substrate 1700. For example, during the process of depositing the thin film 2020 on the substrate 1700 and patterning the deposited thin film 2020, a deviation in the coefficient of thermal expansion (CTE) between the substrate 1700 and the thin film 2020 occurs. This deviation in the coefficient of thermal expansion causes the thin film 2020 to exert the tensile stress 2021 on the substrate 1700, which increases the bending and warpage value of the substrate 1700.

The thin films 2010 and 2020 described in FIGS. 15 and 16 refer to the inorganic film 1910 (see FIG. 13) or the metal 1810 (see FIG. 13) deposited on the substrate 1700 of the mask MK. Therefore, the inorganic film or metal deposited on the substrate 1700 of the mask MK may exert compressive stress or tensile stress on the substrate 1700 depending on its property, and the substrate 1700 may be bent by this stress. The bending of the substrate 1700 may cause defects such as tearing of the mask membrane MM, and thus, a method for reducing the bending, e.g.,, the warpage value, of the substrate 1700 is desired or required.

As in the comparative example of FIGS. 13 and 14, if (e.g., when) the metal 1810 having a property (e.g., a material that exerts compressive stress on the substrate 1700) opposite to the property (e.g., a material that exerts tensile stress on the substrate 1700) of the inorganic film 1910 is arranged at the outer edge of the substrate 1700, the metal 1810 arranged at the outer edge of the substrate 1700 may serve to further increase the bending of the substrate 1700.

For example, if (e.g., when) the metal 1810 having a property (e.g., a material that exerts compressive stress on the substrate 1700) opposite to the property (e.g., a material that exerts tensile stress on the substrate 1700) of the inorganic film 1910 is arranged at the outer edge of the substrate 1700, as shown in FIG. 17, the warpage of the substrate 1700 may have a first value W1.

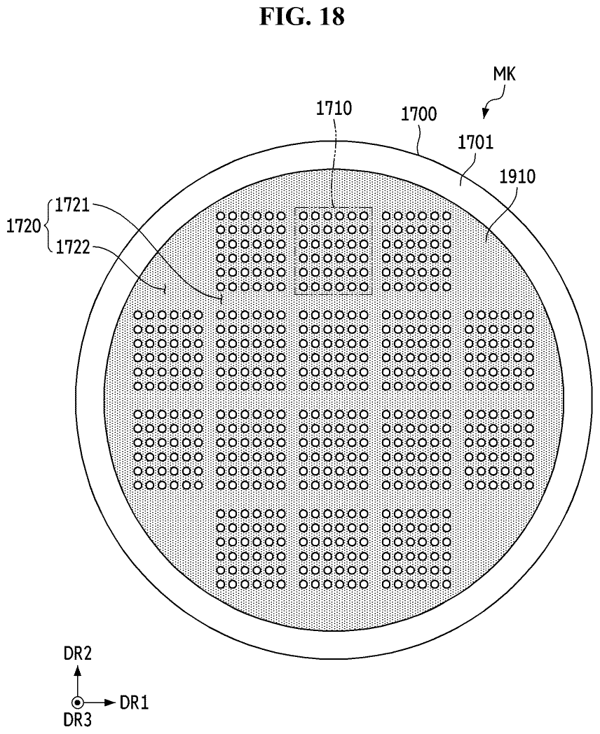

One embodiment of the present disclosure includes design structures for improving the warpage of the substrate 1700 having the first value W1 in the comparative example of FIGS. 13 and 14. Hereinafter, one or more embodiments of the present disclosure for reducing the warpage of the substrate 1700 will be described with reference to FIGS. 18 to 26.

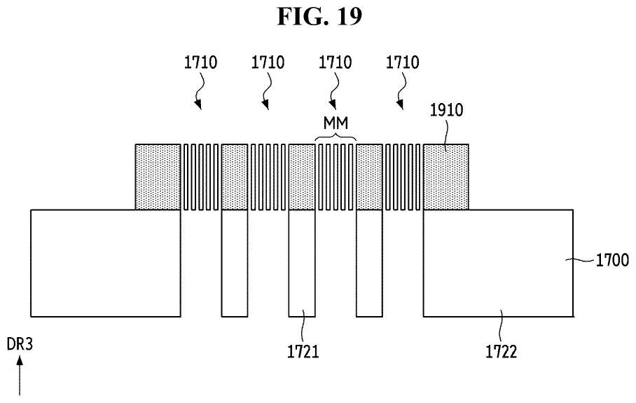

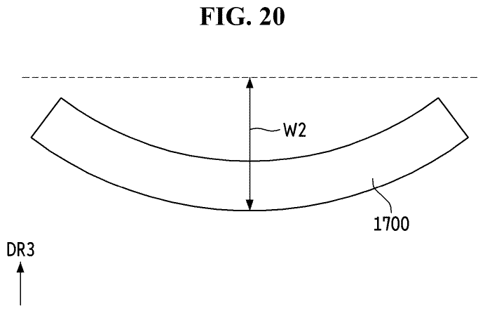

FIG. 18 is a schematic plan view of a mask according to one or more embodiments. FIG. 19 is a cross-sectional view of the mask shown in FIG. 18. FIG. 20 is a conceptual diagram illustrating the warpage of the mask shown in FIG. 18.

Referring to FIGS. 18 and 19, the mask MK according to one or more embodiments differs from that in the comparative example of FIGS. 13 and 14 in that the metal 1810 (see FIG. 13), which serves to further increase the bending of the substrate 1700 at the outer edge of the substrate 1700, is removed.

Referring to FIGS. 18 and 19, the mask MK according to one or more embodiments includes the substrate 1700 (e.g., 1700 of FIG. 12), and the inorganic film 1910 is arranged on the substrate 1700.

At least a portion of the inorganic film 1910 is patterned in each of the plurality of cell regions 1710 to form the mask membrane MM. For example, the inorganic film 1910 may be the first type (kind) inorganic film 1910, which is a material that exerts tensile stress on the substrate 1700, or the second type (kind) inorganic film 1910, which is a material that exerts compressive stress on the substrate 1700.

For example, the inorganic film 1910 may include silicon nitride (SiNₓ), and silicon nitride (SiNₓ) may be a material that exerts tensile stress on the substrate 1700 after being deposited on the substrate 1700.

The mask membrane MM may include the inorganic film 1910 and the plurality of mask openings. The mask membrane MM may be exposed from the rear surface of the substrate 1700 through the cell opening COP (see FIG. 11) formed by etching the rear surface of the substrate 1700.

Around the plurality of cell regions 1710, the mask lip region 1721 is arranged to be around (e.g., surround) each cell region. In addition, the outer frame region 1722 is arranged outside the entire plurality of cell regions 1710. The inorganic film 1910 (e.g., a dummy inorganic film) that remains not patterned is arranged in the mask lip region 1721 and a portion of the outer frame region 1722.

In the outer frame region 1722, at least one alignment key for aligning the mask MK is arranged outside the inorganic film 1910. For example, the metal for forming the alignment key may have a property opposite to that of the inorganic film 1910. For example, the inorganic film 1910 may be a material that exerts tensile stress on the substrate 1700 after being deposited on the substrate 1700, whereas the metal for forming the alignment key may be a material that exerts compressive stress on the substrate 1700, contrary to the inorganic film 1910.

In one or more embodiments of the present disclosure, the alignment key is formed utilizing the metal having a property (e.g., a material that exerts compressive stress on the substrate 1700) opposite to the property (e.g., a material that exerts tensile stress on the substrate 1700) of the inorganic film 1910, and the remaining portion of the metal, excluding the alignment key, may all be removed by patterning. In one or more embodiments of the present disclosure, the bending and warpage of the substrate 1700 may be reduced by removing the metal 1810 (see FIG. 13), which serves to further increase the bending of the substrate 1700 in the comparative example of FIGS. 13 and 14, from the outer edge (e.g., the outer frame region 1722) of the substrate 1700.

For example, as shown in FIG. 20, if (e.g., when) the metal 1810 (see FIG. 13) having a property (e.g., a material that exerts compressive stress on the substrate 1700) opposite to the property (e.g., a material that exerts tensile stress on the substrate 1700) of the inorganic film 1910 is removed from the outer edge of the substrate 1700, the warpage of the substrate 1700 may have a second value W2 less than the first value W1 of FIG. 17.

One embodiment of the present disclosure may additionally include a warpage compensation pattern to improve the warpage of the substrate 1700 described with reference to FIGS. 18 to 20 to have a value less than the second value W2. Hereinafter, one or more embodiments of the present disclosure additionally including the warpage compensation pattern will be described.

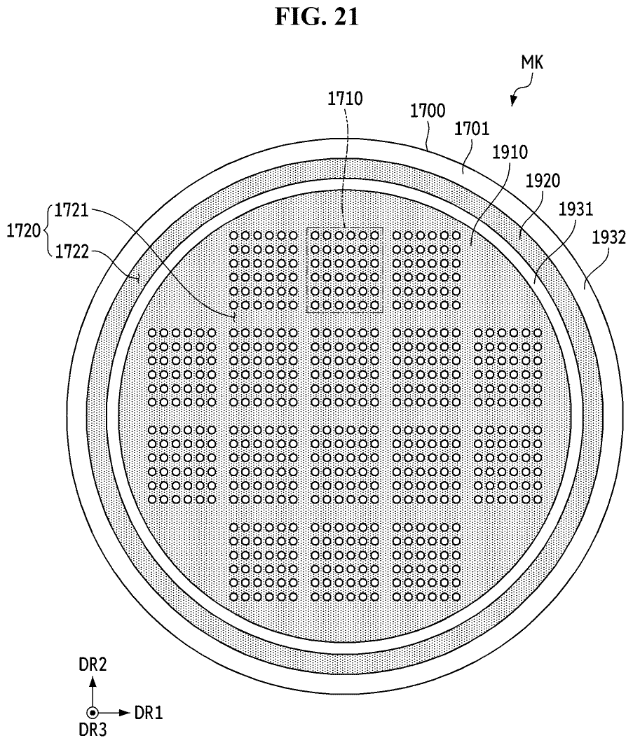

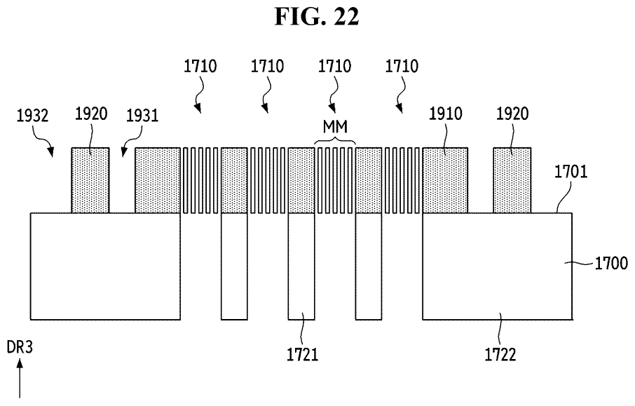

FIG. 21 is a schematic plan view of a mask according to one or more embodiments. FIG. 22 is a cross-sectional view of the mask shown in FIG. 21.

Referring to FIGS. 21 and 22, the mask MK according to one or more embodiments differs from that in one or more embodiments of FIGS. 18 and 19 in that a warpage compensation pattern for compensating for the bending, e.g., the warpage, of the substrate 1700 is additionally arranged at (e.g., disposed at) the outer edge of the substrate 1700. The warpage compensation pattern is formed by a second inorganic film 1920.

Referring to FIGS. 21 and 22, the substrate 1700 includes the plurality of cell regions 1710, the mask lip region 1721 partitioning the plurality of cell regions 1710, and the outer frame region 1722 arranged (e.g., disposed) outside the plurality of cell regions 1710.

According to one or more embodiments, the first inorganic film 1910 forming the mask membrane MM and the warpage compensation pattern for reducing the bending of the substrate 1700 are arranged on (e.g., disposed on) the substrate 1700.

The mask membrane MM includes the first inorganic film 1910 arranged on (e.g., disposed on) the substrate 1700 corresponding to the plurality of cell regions 1710.

The warpage compensation pattern includes the second inorganic film 1920 arranged on (e.g., disposed on) the substrate 1700 corresponding to the outer frame region 1722.

The material of the first inorganic film 1910 is a material that exerts stress on the substrate 1700 in a first reference direction, and the material of the second inorganic film 1920 is a material that exerts stress on the substrate 1700 in the first reference direction. For example, the material of the first inorganic film 1910 constituting the mask membrane MM and the material of the second inorganic film 1920 constituting the warpage compensation pattern may each be a material that exerts stress on the substrate 1700 in the first reference direction and may have the same characteristics.

According to one or more embodiments, the stress in the first reference direction may be compressive stress. In this case, each of the material of the first inorganic film 1910 constituting the mask membrane MM and the material of the second inorganic film 1920 constituting the warpage compensation pattern may be a material that exerts compressive stress on the substrate 1700.

According to one or more embodiments, the stress in the first reference direction may be tensile stress. In this case, each of the material of the first inorganic film 1910 constituting the mask membrane MM and the material of the second inorganic film 1920 constituting the warpage compensation pattern may be a material that exerts tensile stress on the substrate 1700.

According to one or more embodiments, the material of the first inorganic film 1910 and the material of the second inorganic film 1920 may be the same. For example, the first inorganic film 1910 and the second inorganic film 1920 may include silicon nitride (SiNₓ), but the present disclosure is not limited thereto. For example, each of the first inorganic film 1910 and the second inorganic film 1920 may include at least one material selected from among silicon (Si), silicon nitride (SiNₓ), silicon oxynitride (SiON), silicon oxide (SiOₓ), titanium oxide (TiOₓ), amorphous silicon (a-Si), and/or aluminum oxide (AlOₓ).

According to one or more embodiments, the warpage compensation pattern is arranged in a ring shape around (e.g., surrounding) the periphery of the plurality of cell regions 1710. For example, the warpage compensation pattern may be arranged to be around (e.g., surround) the periphery of the first inorganic film 1910 forming the mask membrane MM in the outer frame region 1722.

According to one or more embodiments, a first exposed region 1931 of the substrate 1700, where the first inorganic film 1910 and the second inorganic film 1920 are removed to expose a surface 1701 of the substrate 1700, may be arranged between the second inorganic film 1920 forming the warpage compensation pattern and the plurality of cell regions 1710.

According to one or more embodiments, a second exposed region 1932 of the substrate 1700, where the first inorganic film 1910 and the second inorganic film 1920 are removed to expose the surface 1701 of the substrate 1700, may be arranged outside the warpage compensation pattern.

According to one or more embodiments, the mask MK may further include the alignment key. In the mask MK, the alignment key is provided (e.g., formed) utilizing the metal having a property (e.g., a material that exerts compressive stress on the substrate 1700) opposite to the properties (e.g., a material that exerts tensile stress on the substrate 1700) of the first inorganic film 1910 and the second inorganic film 1920, and the remaining portion of the metal, excluding the alignment key, may be removed by patterning.

For example, if (e.g., when) the first inorganic film 1910 and the second inorganic film 1920 are materials that exert compressive stress on the substrate 1700 in the first reference direction, the mask MK may further include the alignment key including the first metal arranged in a portion of the outer frame region 1722. Here, the first metal is a material that exerts tensile stress on the substrate 1700, and the first metal is not arranged in the remaining portion of the outer frame region 1722 except for the portion of the outer frame region where the alignment key is arranged. For example, the materials of the first inorganic film 1910 and the second inorganic film 1920 may include silicon nitride (SiNₓ), and the material of the first metal may include tungsten (W).

For example, if (e.g., when) the first inorganic film 1910 and the second inorganic film 1920 are materials that exert tensile stress on the substrate 1700 in the first reference direction, the mask MK may further include the alignment key including the second metal arranged in (e.g., disposed in) a portion of the outer frame region 1722. Here, the second metal is a material that exerts compressive stress on the substrate 1700, and the second metal is not arranged in (e.g., disposed in) the remaining portion of the outer frame region 1722 except for the portion of the outer frame region where the alignment key is arranged.

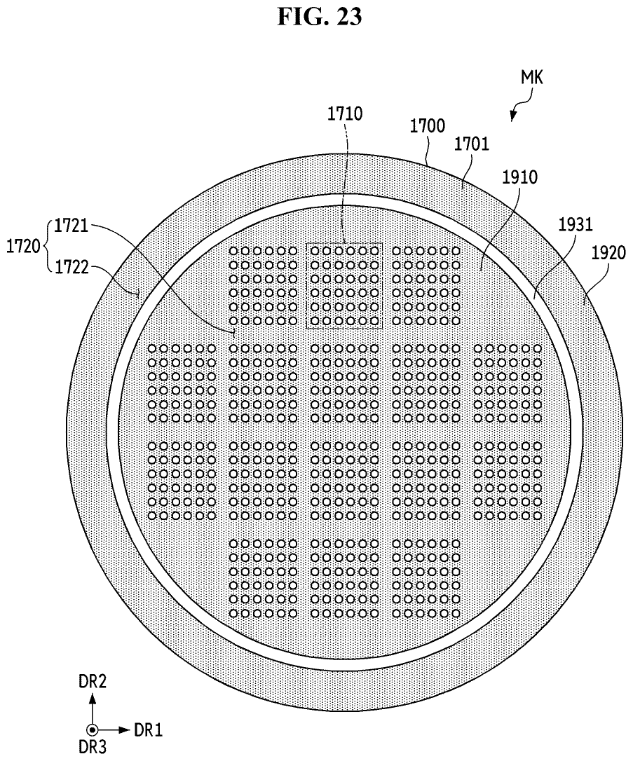

FIG. 23 is a plan view of a mask according to one or more embodiments in which the area of a warpage compensation pattern is enlarged.

The embodiment of FIG. 23 differs from one or more embodiments of FIG. 21 in that the second inorganic film 1920 forming the warpage compensation pattern is arranged (e.g., disposed) to extend to the outermost boundary of the substrate 1700. For example, the second inorganic film 1920 forming the warpage compensation pattern may be arranged (e.g., disposed) to extend to the outermost boundary of the substrate 1700, and accordingly, the second exposed region 1932 (see FIG. 21) of the substrate 1700, where the first inorganic film 1910 and the second inorganic film 1920 are removed to expose the surface 1701 of the substrate 1700, may not be arranged (e.g., disposed) outside the warpage compensation pattern.

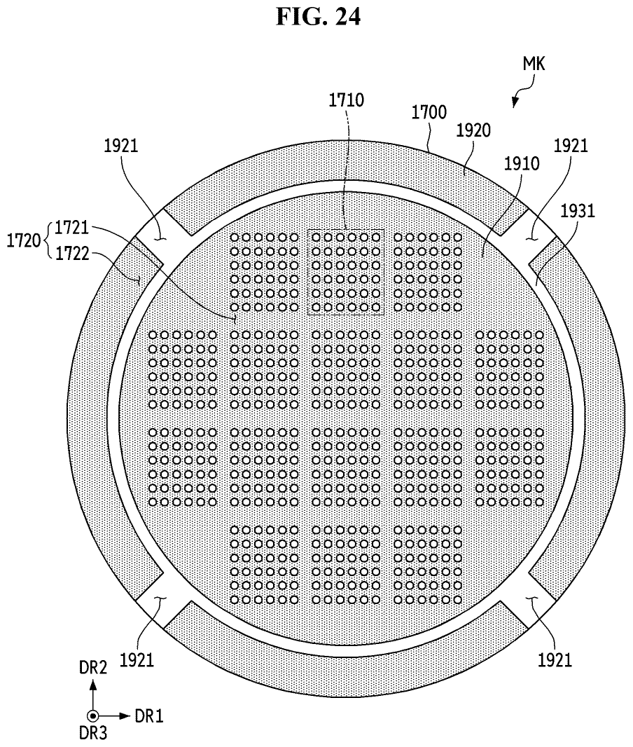

FIG. 24 is a plan view of a mask according to one or more embodiments in which a warpage compensation pattern includes a slit.

The one or more embodiments of FIG. 24 differ from the one or more embodiments of FIG. 23 in that the warpage compensation pattern includes a slit 1921. For example, the warpage compensation pattern around (e.g., surrounding) the first inorganic film 1910 forming the mask membrane MM may be arranged in the outer frame region 1722 of the mask MK, and the warpage compensation pattern may include at least one slit 1921 that exposes the surface 1701 of the substrate 1700.

According to one or more embodiments, the slits 1921 of the warpage compensation pattern may be arranged at specified intervals. Accordingly, the stress exerted on the substrate 1700 by the warpage compensation pattern may be symmetrical from a global view of the substrate 1700, and the effect of improving the warpage of the substrate 1700 may be uniformly (e.g., substantially uniformly) applied across the entire substrate 1700.

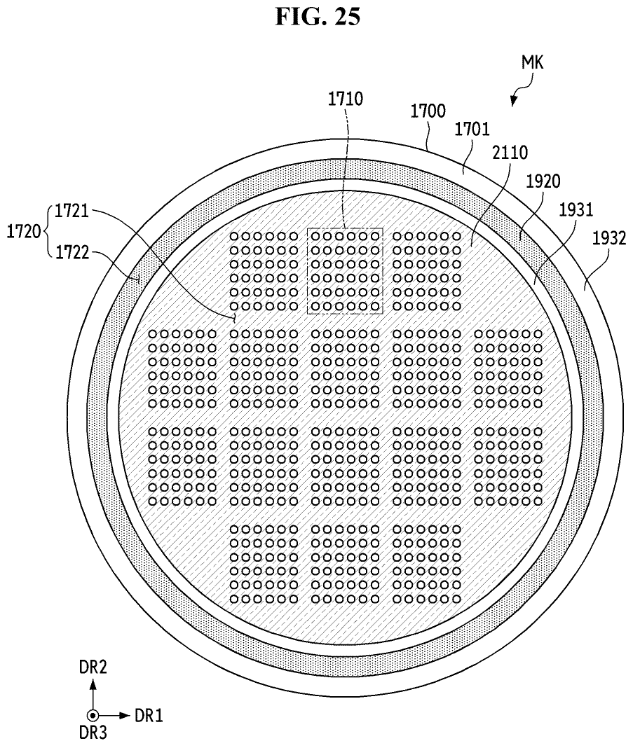

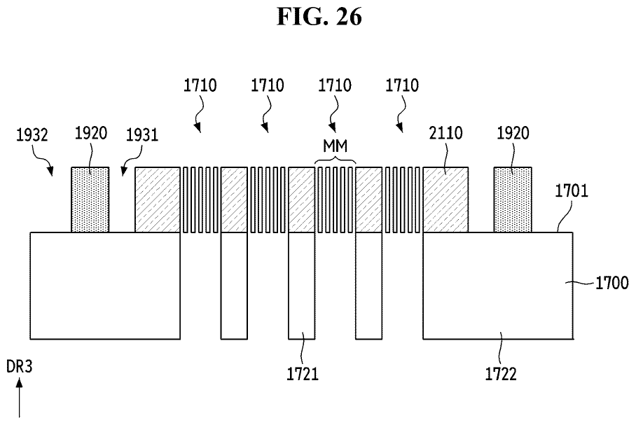

FIG. 25 is a plan view of a mask according to one or more embodiments in which a mask membrane includes (e.g., is formed of) a plating film. FIG. 26 is a cross-sectional view of the mask shown in FIG. 25.

The one or more embodiments of FIGS. 25 and 26 differs from the one or more embodiments of FIGS. 21 and 22 in that the mask membrane MM include (e.g., is formed of) a plating film 2110.

The plating film 2110 may be provided by (e.g., formed by) a damascene process, e.g., electroplating or electroforming method. The plating film 2110 may include tungsten (W) and/or copper (Cu).

According to one or more embodiments, the substrate 1700 of the mask MK includes the plurality of cell regions 1710, the mask lip region 1721 partitioning the plurality of cell regions 1710, and the outer frame region 1722 arranged outside the plurality of cell regions 1710.

The plating film 2110 is arranged on the substrate 1700 corresponding to the plurality of cell regions 1710, and the plating film 2110 is patterned to form the mask membrane MM.

The warpage compensation pattern including an inorganic film is arranged on the substrate 1700 corresponding tofggfgfgh the outer frame region 1722.

According to one or more embodiments, the material of the plating film 2110 is a material that exerts stress on the substrate 1700 in the first reference direction, and the material of the inorganic film is a material that exerts stress on the substrate 1700 in the first reference direction.

The warpage compensation pattern may be arranged in (e.g., disposed in) a ring shape around (e.g., surrounding) the periphery of the plurality of cell regions 1710.

The warpage compensation pattern may include at least one slit that exposes the surface 1701 of the substrate 1700.

The first exposed region 1931 of the substrate 1700, where the inorganic film is removed to expose the surface 1701 of the substrate 1700, may be arranged between the warpage compensation pattern and the plurality of cell regions 1710.

The second exposed region 1932 of the substrate 1700, where the inorganic film is removed to expose the surface 1701 of the substrate 1700, may be arranged (e.g., disposed) outside the warpage compensation pattern.

According to one or more embodiments, the stress exerted by the plating film 2110 on the substrate 1700 in the first reference direction may be compressive stress. In this case, the mask MK further includes the alignment key including the first metal arranged (e.g., disposed) in a portion of the outer frame region 1722. The first metal is a material that exerts tensile stress on the substrate 1700, and the first metal is not arranged (e.g., disposed) in the remaining portion of the outer frame region 1722 except for the portion of the outer frame region where the alignment key is arranged (e.g., disposed).

According to one or more embodiments, the stress exerted by the plating film 2110 on the substrate 1700 in the first reference direction may be tensile stress. In this case, the mask MK further includes the alignment key including the second metal arranged in (e.g., disposed in) a portion of the outer frame region 1722. The second metal is a material that exerts compressive stress on the substrate 1700, and the second metal is not arranged in (e.g., disposed in) the remaining portion of the outer frame region 1722 except for the portion of the outer frame region where the alignment key is arranged (e.g., disposed). Because stress (e.g., tensile stress and/or compressive stress) often occurs in a substrate of a deposition mask and thin films stacked on the substrate of the deposition mask, to reduce such stress which may cause warpage, the substrate according to one or more embodiments may include an alignment key including a metal that exerts the stress to counteract the stress exerted by the plating film. Furthermore, the thin films stacked on the substrate may also include a metal that exerts the stress to counteract the stress exerted by the plating film. Therefore, bending characteristics of the substrate may be improved (e.g., flexibility and reduced warpage). That is, the alignment key and/or the thin films may exert stress to counteract the stress exerted by the plating film, thereby reducing warpage and improving the bending characteristics of the substrate.

In the context of the present application and unless otherwise defined, the terms “use,” “using,” and “used” may be considered synonymous with the terms “utilize,” “utilizing,” and “utilized,” respectively.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It should be understood, however, that the aspects and features of embodiments of the present disclosure are not restricted to the one set forth herein.

The above and other aspects of the present disclosure will become more apparent to one of ordinary skill in the art to which the present disclosure pertains by referencing the claims, with equivalents thereof to be included therein.

What is claimed is:

1. A deposition mask comprising:
a substrate comprising a plurality of cell regions, a mask lip region partitioning the plurality of cell regions, and an outer frame region outside the plurality of cell regions;
a mask membrane comprising a first inorganic film on the substrate corresponding to the plurality of cell regions; and
a warpage compensation pattern comprising a second inorganic film on the substrate corresponding to the outer frame region,
wherein a material of the first inorganic film is a material configured to exert stress on the substrate in a first reference direction, and
wherein a material of the second inorganic film is a material configured to exert stress on the substrate in the first reference direction.

2. The deposition mask of claim 1, wherein the material of the first inorganic film and the material of the second inorganic film are the same.

3. The deposition mask of claim 1, wherein the warpage compensation pattern is in a ring shape around a periphery of the plurality of cell regions.

4. The deposition mask of claim 3, wherein the warpage compensation pattern comprises at least one slit exposing a surface of the substrate.

5. The deposition mask of claim 4, wherein a first exposed region of the substrate, where the first inorganic film and the second inorganic film are removed to expose the surface of the substrate, is between the warpage compensation pattern and the plurality of cell regions.

6. The deposition mask of claim 4, wherein a second exposed region of the substrate, where the first inorganic film and the second inorganic film are removed to expose the surface of the substrate, is outside the warpage compensation pattern.

7. The deposition mask of claim 1, wherein the stress in the first reference direction is compressive stress.

8. The deposition mask of claim 7, further comprising an alignment key comprising a first metal in a portion of the outer frame region,
wherein the first metal is a material that exerts tensile stress on the substrate, and
wherein the first metal is not in a remaining portion of the outer frame region except for the portion of the outer frame region where the alignment key is.

9. The deposition mask of claim 8, wherein materials of the first inorganic film and the second inorganic film comprise silicon nitride (SiNₓ), and wherein a material of the first metal comprises tungsten (W).

10. The deposition mask of claim 1, wherein the stress in the first reference direction is tensile stress.

11. The deposition mask of claim 10, further comprising an alignment key comprising a second metal in a portion of the outer frame region,
wherein the second metal is a material that exerts compressive stress on the substrate, and
wherein the second metal is not in a remaining portion of the outer frame region except for the portion of the outer frame region where the alignment key is.

12. A deposition mask comprising:
a substrate comprising a plurality of cell regions, a mask lip region partitioning the plurality of cell regions, and an outer frame region outside the plurality of cell regions;
a mask membrane comprising a plating film on the substrate corresponding to the plurality of cell regions; and
a warpage compensation pattern comprising an inorganic film on the substrate corresponding to the outer frame region,
wherein a material of the plating film is a material configured to exert stress on the substrate in a first reference direction, and
wherein a material of the inorganic film is a material configured to exert stress on the substrate in the first reference direction.

13. The deposition mask of claim 12, wherein the warpage compensation pattern is in a ring shape around a periphery of the plurality of cell regions.

14. The deposition mask of claim 13, wherein the warpage compensation pattern comprises at least one slit exposing a surface of the substrate.

15. The deposition mask of claim 14, wherein a first exposed region of the substrate, where the plating film and the inorganic film are removed to expose the surface of the substrate, is between the warpage compensation pattern and the plurality of cell regions.

16. The deposition mask of claim 14, wherein a second exposed region of the substrate, where the plating film and the inorganic film are removed to expose the surface of the substrate, is outside the warpage compensation pattern.

17. The deposition mask of claim 12, wherein the stress in the first reference direction is compressive stress.

18. The deposition mask of claim 17, further comprising an alignment key comprising a first metal in a portion of the outer frame region,
wherein the first metal is a material that exerts tensile stress on the substrate, and
wherein the first metal is not in a remaining portion of the outer frame region except for the portion of the outer frame region where the alignment key is.

19. The deposition mask of claim 12, wherein the stress in the first reference direction is tensile stress.

20. The deposition mask of claim 19, further comprising an alignment key comprising a second metal in a portion of the outer frame region,
wherein the second metal is a material that exerts compressive stress on the substrate, and
wherein the second metal is not in a remaining portion of the outer frame region except for the portion of the outer frame region where the alignment key is.

21. An electronic or electric device is formed by a deposition mask:
the deposition mask comprising:
a substrate comprising a plurality of cell regions, a mask lip region partitioning the plurality of cell regions, and an outer frame region outside the plurality of cell regions;
a mask membrane comprising a first inorganic film on the substrate corresponding to the plurality of cell regions; and
a warpage compensation pattern comprising a second inorganic film on the substrate corresponding to the outer frame region,
wherein a material of the first inorganic film is a material configured to exert stress on the substrate in a first reference direction, and
wherein a material of the second inorganic film is a material configured to exert stress on the substrate in the first reference direction; or
the deposition mask comprising:
a substrate comprising a plurality of cell regions, a mask lip region partitioning the plurality of cell regions, and an outer frame region outside the plurality of cell regions;
a mask membrane comprising a plating film on the substrate corresponding to the plurality of cell regions; and
a warpage compensation pattern comprising an inorganic film on the substrate corresponding to the outer frame region,
wherein a material of the plating film is a material configured to exert stress on the substrate in a first reference direction, and
wherein a material of the inorganic film is a material configured to exert stress on the substrate in the first reference direction.
